(19) United States
(12) Patent Application Publication
(10) Pub. No.: US 2009/0249171 A1
(43) Pub. Date: Oct. 1, 2009

(54) TURBO DECODER, BASE STATION AND DECODING METHOD

(75) Inventor: Kiyotaka Yago, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/412,123

(22) Filed: Mar. 26, 2009

(30) Foreign Application Priority Data
Mar. 28, 2008 (JP) 2008-087865

(51) Int. Cl. H03M 13/03; G06F 11/10

(52) U.S. Cl. 714/786; 714/E11.032

(57) ABSTRACT

A turbo decoder includes a state transition probability computing unit which obtains a state transition probability from data, a flag, and a priori probability from a previous stage, an alpha and beta metric computing unit which obtains an alpha metric and a beta metric from the state transition probability by computing a plurality of processes concurrently in a time sequence, and a normalization unit which obtains decoded data and a priori probability for a next stage based on the state transition probability obtained by the state transition probability computing unit and on the alpha metric and the beta metric obtained by the alpha and beta metric computing unit.

### CROSS-REFERENCE TO RELATED APPLICATION

This application is based upon and claims the benefit of priority of the prior Japanese Patent Application No. 2008-87865, filed on Mar. 28, 2008, the entire contents of which are incorporated herein by reference.

### FIELD

An embodiment of the present invention relates to a turbo decoder which decodes a turbo code, a base station including the turbo decoder, and a decoding method for the turbo code. The turbo decoder, the base station, and the decoding method include, for example, a technique for speeding up alpha and beta computation and reducing the amount of memory.

### BACKGROUND

A method using turbo codes is attracting attention as an encoding method for approaching the Shannon limit. A turbo code is based on the “turbo principle” that the error rate of data encoded by two or more convolutional encoders statistically uncorrelated with each other on the transmitting side is reduced by repeatedly performing a recursive operation on the data using the correlation absence on the receiving side.

The general configuration of a turbo encoder which performs turbo encoding will first be described. FIG. 1 is a block diagram illustrating the general configuration of a turbo encoder.

A turbo encoder 10 illustrated in FIG. 1 divides data to be transmitted into sequences A and B of even and odd data in a distributor 11 and computes and transmits flag bits Y1 and W1 in a convolutional encoder 12. Since burst data is sensitive to noise which occurs in a burst, the turbo encoder 10 changes the order of each data sequence in an interleaver 13, computes flag bits Y2 and W2 in a convolutional encoder 14, and transmits the flag bits Y2 and W2. The turbo encoder 10 does not necessarily transmit all of the flag bits Y1, W1, Y2, and W2 at the same time. For example, the turbo encoder 10 performs the process of transmitting some of the flag bits and, if an error occurs on the receiving side, transmitting other bits in combination.

The convolutional encoders 12 and 14 basically have the same configuration, and the configuration is illustrated in FIG. 1 in an enlarged scale.

Code computation defined by IEEE 802.16 (WiMAX) is illustrated in the example in FIG. 1. Other communication systems (e.g., CDMA) may be different in code computation expression but have basically the same configuration.

Processing in a turbo decoder which decodes a turbo code will be described. An overview of a maximum a posteriori probability (MAP) decoding algorithm using trellis state transitions, which is one turbo code decoding method, will first be described before describing the configuration of a turbo decoder.

To decode a convolutional data sequence generated by the turbo encoder illustrated in FIG. 1, a method of estimating a data sequence from a transition state by computing a transition probability using a trellis and giving a score for each transition is used, as illustrated in FIG. 2. FIG. 2 illustrates an example of trellis state transitions.

A turbo decoder is configured to increase a transition probability by repeating a trellis transition (see FIG. 3). In a turbo decoder, a trellis in which data is caused to transition in the backward direction (see FIG. 4) is prepared for decoding called maximum a posteriori probability decoding (MAP decoding), in addition to a trellis in which data is caused to transition in the forward direction. A forward computation is called an α metric, and a backward computation is called a β metric. A combined MAP algorithm performs more accurate estimation by taking the two computational methods into consideration.

An α transition and a β transition depend on transitions of registers S1, S2, and S3 of the convolutional encoders 12 and 14 of the turbo encoder 10 illustrated in FIG. 1. α and β each increase the number of weights while transitioning. The numbers of weights are passed to a circuit in the next stage as α and β values. FIG. 6 illustrates an example of actual α metric values. The columns correspond to trellis 0, . . . , trellis 7, starting from the left.

Based on the above, the configuration of a turbo decoder will be described. FIG. 5 is a block diagram illustrating the general configuration of a single turbo decoder. The (single) turbo decoder 50 illustrated in FIG. 5 has a state transition probability computing unit 51, a λ normalization unit 52, a forward trellis α 53, and a backward trellis β 54.

The state transition probability computing unit 51 obtains a state transition probability γ from data A and B, flags Y and W, and a priori probability Le from the previous stage. The forward trellis α 53 and backward trellis β 54 perform forward and backward trellis computations, respectively, based on the state transition probability γ obtained by the state transition probability computing unit 51. The λ normalization unit 52 obtains decoded data and the priori probability Le from the state transition probability γ obtained by the state transition probability computing unit 51 and α and β which are results of the forward and backward trellis computations performed by the forward trellis α 53 and backward trellis β 54. The priori probability Le is transmitted to a single turbo decoder in the next stage.

In order to increase trellis reliability, a trellis twice as long as decoded data is used. Let A0 to An, B0 to Bn, Y0 to Yn, and W0 to Wn be input data sequences, and γ0 to γn be obtained γ values. Since when γ0 to γn serve as inputs for α and β, there are eight states, a trellis is searched in the manner below. A first set of γ0 to γn is used only to increase trellis transition accuracy and is not used as λ inputs.

A single turbo decoder has been described above. A turbo decoder performs same processing on a code interleaved to increase a decoding ratio against burst noise. An overall turbo decoder thus has a configuration as illustrated in FIG. 7. FIG. 7 is a block diagram illustrating the general configuration of an overall turbo decoder.

An overall turbo decoder 60 illustrated in FIG. 7 has a single turbo decoder 61 which obtains a priori probability Le upon receipt of inputted data sequences A and B and flags Y1 and W1. The single turbo decoder 61 corresponds to the single turbo decoder 50 illustrated in FIG. 5. The priori probability Le obtained in the single turbo decoder 61 is inputted to an interleaver 62 and is interleaved. The priori probability Le, which has been interleaved by the interleaver 62, and input data sequences A′ and B′ which have been interleaved by an interleaver 63 are inputted to a single turbo decoder 64. The single turbo decoder 64 corresponds to the single turbo decoder 50 illustrated in FIG. 5. The turbo decoder 64 obtains the priori probability Le upon receipt of the inputs and inputted flags Y2 and W2. The priori probability obtained by the single turbo decoder 64 is deinterleaved in a deinterleaver 65 and is inputted to the turbo decoder 61 as data for the next stage.

On the decoder side, data obtained after normalization using forward search and backward search trellises in combination is accumulated as the priori probability Le. After an original data sequence is subjected to the processing, a data sequence obtained by interleaving the original data sequence is also subjected to the same processing. The accuracy of the priori probability Le obtained as the result is increased in this manner.

The details of an α metric computation will now be described. FIG. 8 illustrates an α metric computing method. Four types of add operations are performed on eight (2×4) elements of γ computed in the previous stage based on previous α values. The sums are possible trellis paths. If all transitions are left available, enormous memory capacity and processing capacity are required. Accordingly, only a maximum value is selected each time, and the value is set as a new α value. For example, in computation of α(0), addition of α(0) and γ(0,0), addition of α(6) and γ(0,1), addition of α(1) and γ(0,2), and addition of α(7) and γ(0,3) are performed, and only a maximum one of the sums is selected (MAX selection) and is set as a new value of α(0).

As illustrated in FIG. 9, a β value similarly obtained by a backward transition and an α value are chronologically added, and a value with higher accuracy than a previous trellis value is obtained. FIG. 9 is a diagram illustrating (a first half of) a λ computing method. The possibility of each transition is computed based on obtained values.

As illustrated in FIG. 10, a maximum value is acquired from each group of eight λ values obtained in FIG. 9 (maximum value section), and the number of λ (a second argument) with a maximum value of the four values is outputted as a decoding result. Each element of λout represents a probability. For example, λout(0) represents a probability that the output is “00,” λout(1) represents a probability that the output is “01,” λout(2) represents a probability that the output is “10,” and λout(3) represents a probability that the output is “11.”

The details of computation of a priori probability Le will be described. FIG. 11 illustrates an Le computing method. A new value of Le is a value obtained by subtracting elements as A and B and a previous value of Le from a code state transition probability (λout obtained in FIG. 10) and is a probability value indicated by flags Y and W. For example, Le(0) represents a probability that the answer is “00,” Le(1) represents a probability that the answer is “01,” Le(2) represents a probability that the answer is “10,” and Le(3) represents a probability that the answer is “11.”

Le has an initial value of “0.” As illustrated in FIG. 12, the value of Le is updated every time switching between alternating standard processing (non-interleaving) and interleaving occurs, thereby increasing a probability that each bit is correct. In other words, a value outputted at each switching operation is the value of Le. FIG. 12 is a chart illustrating the timing of Le updates.

Various methods have been examined for increased turbo decoder speeds. For example, a turbo decoder is suggested which includes, in order to perform α and β metric computation, a technique for supplying a plurality of pipelined stages of γ metrics, and an ACS computation technique composed of a plurality of stages of cascade connections for receiving the plurality of pipelined γ metrics (see Japanese Patent Laid-Open No. 2001-320282). Also, a turbo decoder is suggested which selects, on the basis of the polarity of a computation result from an adder and the polarity of a selection output from a selector, one of the sum including a negative polarity, the selection result including a negative polarity, a sum of the sum and selection result, and zero by a second selector, wherein an α metric and a β metric are computed on the basis of an output from the second selector (see Japanese Patent Laid-Open No. 2001-24521). Additionally, an apparatus for computing in-place path metric addressing for a trellis processor is suggested (see Japanese Patent Laid-Open No. 2002-152057).

### SUMMARY

According to an aspect of the embodiment discussed herein, a turbo decoder includes a state transition probability computing unit which obtains a state transition probability from data, a flag, and a priori probability from a previous stage, an alpha and beta metric computing unit which obtains an alpha metric and a beta metric from the state transition probability by computing a plurality of processes concurrently in a time sequence, and a normalization unit which obtains decoded data and a priori probability for a next stage based on the state transition probability obtained by the state transition probability computing unit and on the alpha metric and the beta metric obtained by the alpha and beta metric computing unit.

According to another aspect of the embodiment, a turbo decoder includes a state transition probability computing unit which obtains a state transition probability from data, a flag, and a priori probability from a previous stage; an alpha and beta metric computing unit which obtains an alpha metric and a beta metric from the state transition probability obtained by the state transition probability computing unit; a normalization unit which obtains decoded data and a priori probability for a next stage based on the state transition probability obtained by the state transition probability computing unit and on the alpha metric and the beta metric obtained by the alpha and beta metric computing unit; a compression unit which compresses at least one of the alpha metric and the beta metric using an accumulated value of a maximum value of the state transition probability; and a storage unit which stores at least one of the alpha metric and the beta metric compressed by the compression unit.

Additional objects and advantages of the embodiment will be set forth in part in the description which follows, and in part will be understood from the description, or may be learned by practice of the embodiment. The object and advantages of the embodiment will be realized and attained by means of the elements and combinations particularly pointed out in the appended claims.

It is to be understood that both the foregoing summary description and the following detailed description are exemplary and explanatory and are not restrictive of the embodiment, as claimed.

### BRIEF DESCRIPTION OF DRAWINGS

An embodiment is illustrated by way of example and not limited by the following figures.

FIG. 1 is a block diagram illustrating the general configuration of a turbo encoder;

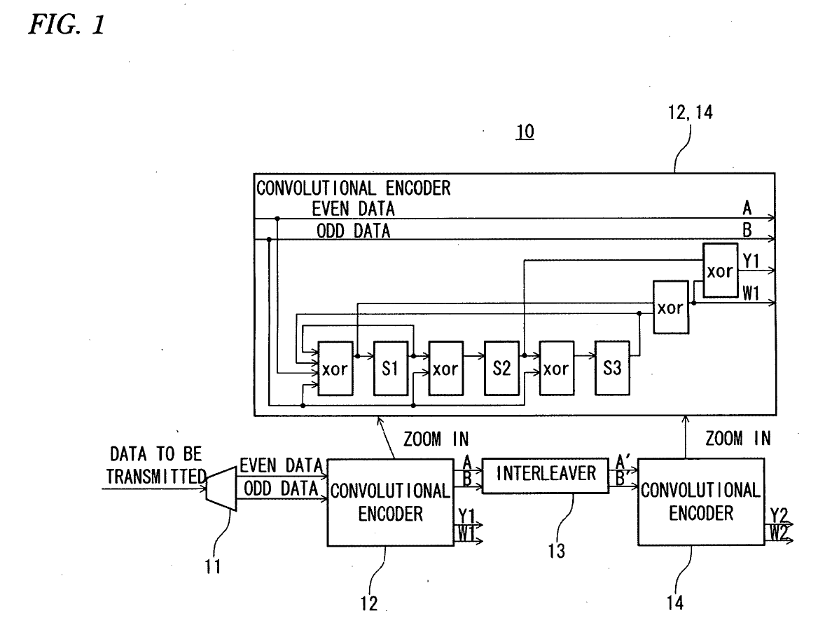

FIG. 2 illustrates an example of trellis state transitions;

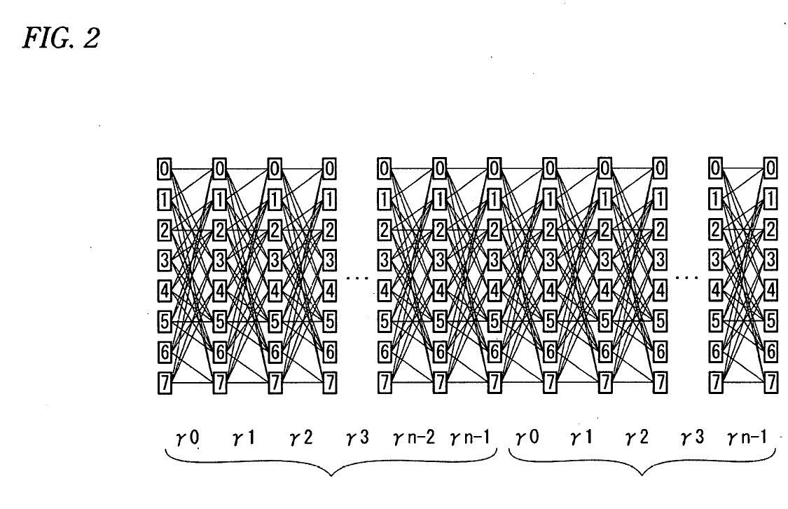

FIG. 3 illustrates an example of α metric state transitions;

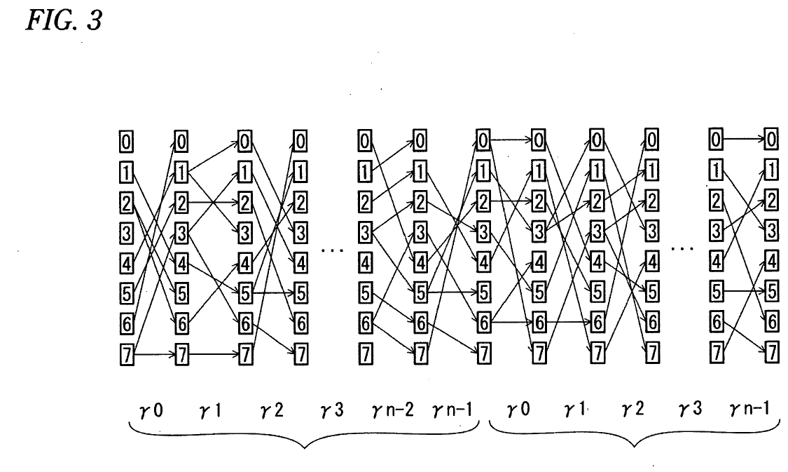

FIG. 4 illustrates an example of β metric state transitions;

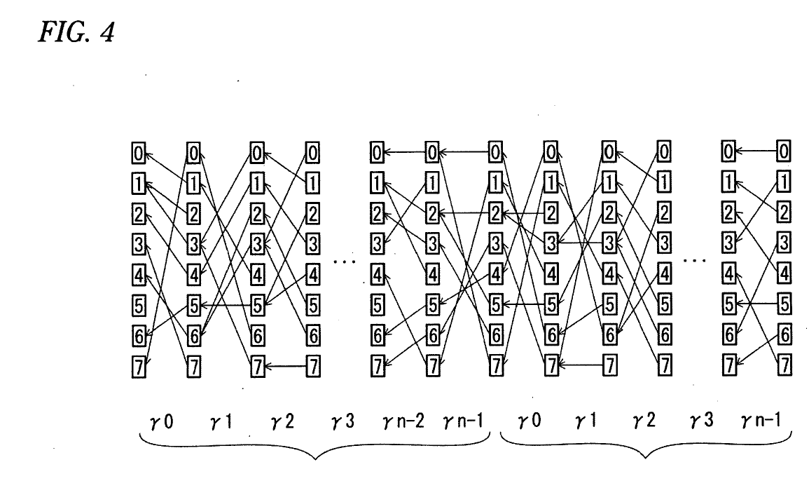

FIG. 5 is a block diagram illustrating the general configuration of a single turbo decoder;

FIG. 6 is a table illustrating an example of actual α metric values;

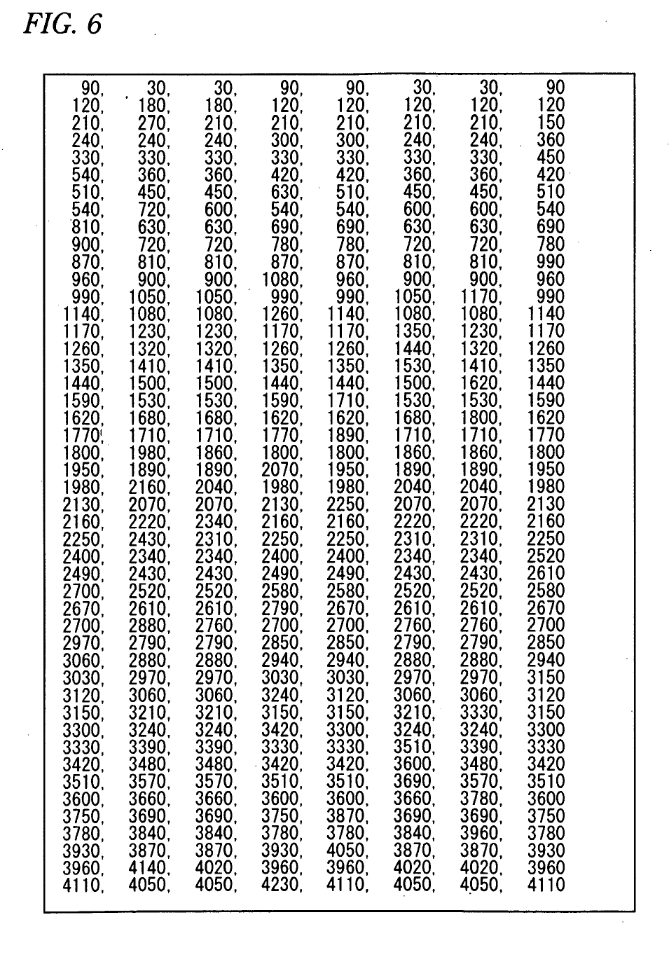

FIG. 7 is a block diagram illustrating the general configuration of an overall turbo decoder;

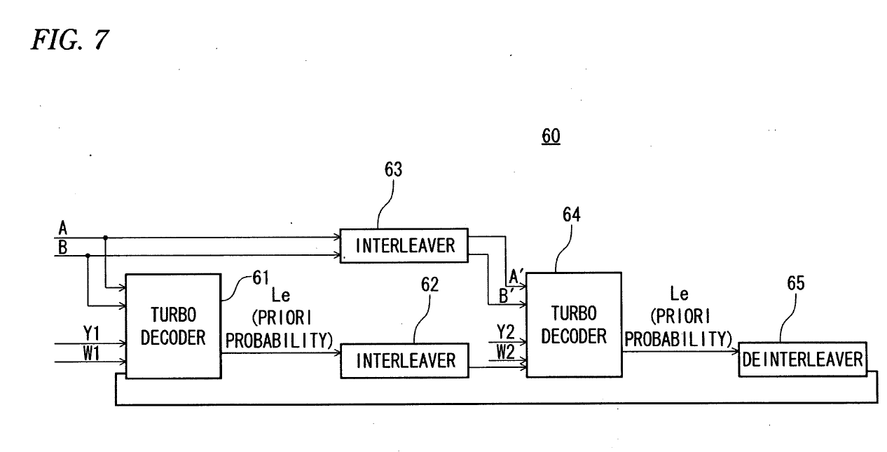

FIG. 8 illustrates an α metric computing method;

FIG. 9 illustrates a first half of a λ computing method;

FIG. 10 illustrates a second half of the λ computing method;

FIG. 11 illustrates an Le computing method;

FIG. 12 is a chart illustrating the timing of Le updates;

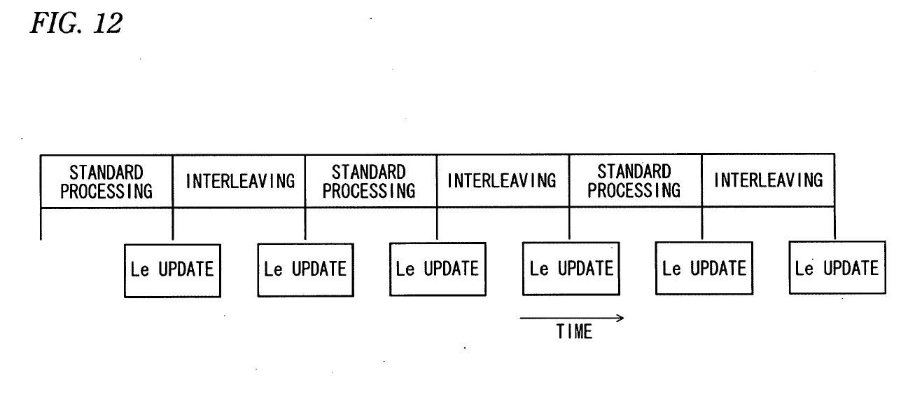

FIG. 13 is a chart for explaining a case where λ metrics are read out in ascending order after the λ metrics are written in descending order;

FIG. 14 illustrates a configuration which performs two processes at one time in α metric computation;

FIG. 15 is a diagram obtained by rearranging the configuration illustrated in FIG. 14;

FIG. 16 is a diagram obtained by further rearranging the configuration illustrated in FIG. 15;

FIG. 17 is a table illustrating computation of two processes for α(0);

FIG. 18 is a table illustrating computation of two processes for α(3);

FIG. 19 is a table illustrating computation of two processes for α(4);

FIG. 20 is a table illustrating computation of two processes for α(7);

FIG. 21 is a table illustrating computation of two processes for α(1);

FIG. 22 is a table illustrating computation of two processes for α(2);

FIG. 23 is a table illustrating computation of two processes for α(5);

FIG. 24 is a table illustrating computation of two processes for α(6);

FIG. 25 is a block diagram illustrating circuitry which performs two α metric processes at one time according to an embodiment;

FIG. 26 is a block diagram illustrating a memory for β metrics and peripheral circuits thereto according to the related art;

FIG. 27 is a block diagram illustrating a memory for β metrics and peripheral circuits thereto according to an embodiment;

FIG. 28 is a chart illustrating a case where α metrics are read out in descending order after the α metrics are written in ascending order;

FIG. 29 is a block diagram illustrating a memory for α metrics and peripheral circuits thereto according to the related art;

FIG. 30 is a block diagram illustrating a memory for α metrics and peripheral circuits thereto according to an embodiment;

FIG. 31 is a block diagram illustrating αβ compression, a memory for β, and peripheral circuits thereto according to an embodiment;

FIG. 32 illustrates an arithmetic circuit for a priori probability Le when αβ compression is performed, according to an embodiment;

FIG. 33 is a block diagram illustrating a first example of a turbo decoder;

FIG. 34 is a time chart illustrating write control according to the first example;

FIG. 35 is a time chart illustrating read control according to the first example;

FIG. 36 illustrates an interleave table according to the first example;

FIG. 37 is a chart illustrating switching between standard processing and interleaving according to the first example;

FIG. 38 is a γ computation correspondence table illustrating γ computation according to the first example;

FIG. 39 is a block diagram illustrating, in detail, an α/β circuit according to the first example;

FIG. 40 is a time chart illustrating αβ switching processing according to the first example;

FIG. 41 is a table illustrating input elements for β(0);

FIG. 42 is a table illustrating input elements for β(1);

FIG. 43 is a table illustrating input elements for β(2);

FIG. 44 is a table illustrating input elements for β(3);

FIG. 45 is a table illustrating input elements for β(4);

FIG. 46 is a table illustrating input elements for β(5);

FIG. 47 is a table illustrating input elements for β(6);

FIG. 48 is a table illustrating input elements for β(7);

FIG. 49 is a block diagram illustrating a second example of a turbo decoder; and

FIG. 50 is a block diagram illustrating a piece of base station equipment using a turbo decoder according to an embodiment of the present invention.

### DESCRIPTION OF EMBODIMENT

As part of present invention, observations were made regarding problems with the related art that the method previously referred to in the Background.

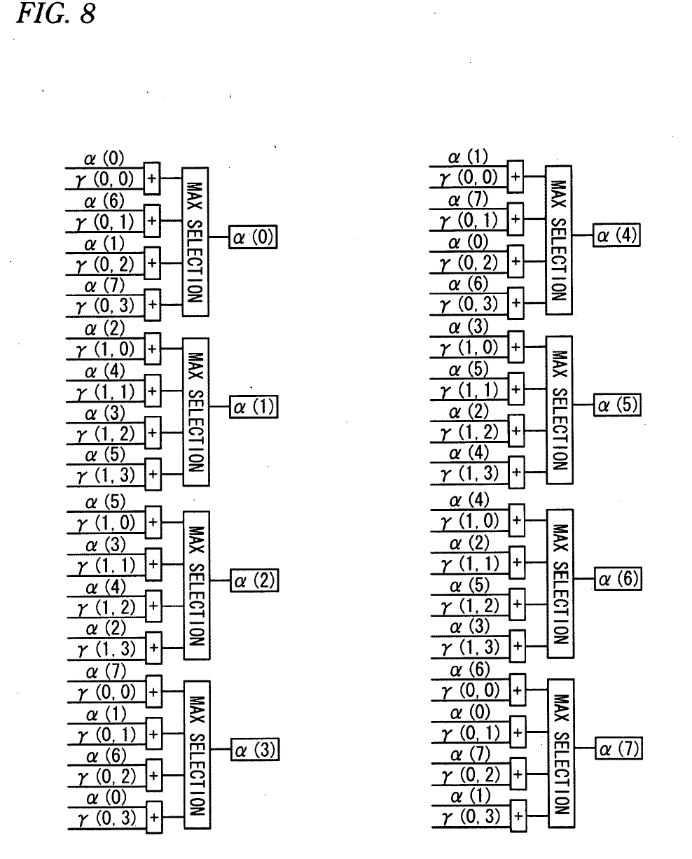

As illustrated in FIG. 8, an α metric is computed by feeding back a value of the α metric obtained the previous time. This causes a bottleneck in higher speed computation. The same problem occurs in β metric computation. More specifically, computation of data at time point n in a time sequence may be started only after data at time point n−1 is computed. Letting “t” be a time period required for one computation, and “n” be the number of pieces of data, a time period t×n is required. For example, assume that the number of bits necessary for the speed of a currently available device is 18. In this case, three clocks (addition, selection of one out of four, and selection of one out of two) are required for one α metric and β metric computation. It is desirable to further shorten the time.

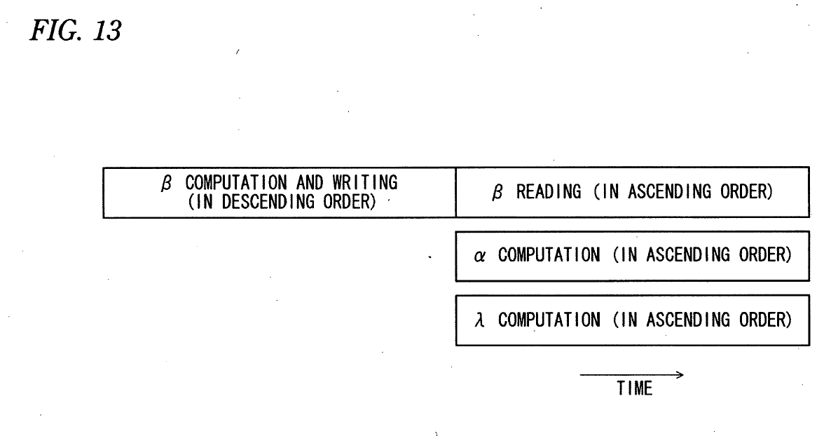

α metric values and β metric values to be computed are chronologically opposite. Accordingly, after β metrics are computed and stored in a memory in descending order, α metrics are computed in ascending order while the stored β metrics are read out in ascending order (chronologically opposite), and λ computation is performed, as illustrated in FIG. 13. As described above, in order to cause the chronological order of α metrics and that of β metrics to match each other, the β metrics are stored in the memory.

For example, in WiMAX, the data size is variable, and the maximum data size is 2,400 words. Since one word equals 18 bits, and 2,400 words may be needed for each of eight states, the size of a memory for storing β metrics is 345,600 bits (2,400×18 bits×8). Since reservation of such a large memory area for storing β metrics in integrated circuit design is currently difficult, it is thus desirable to minimize the size of a memory for storing β metrics.

Hereinafter, examples of an embodiment of the disclosed turbo decoder, a base station including the turbo decoder and a decoding method for the turbo code will be described with reference to the drawings. Throughout the drawings, the same components are denoted by the same reference numerals.

<Reduction in Computation Time of α Metric and β Metric>

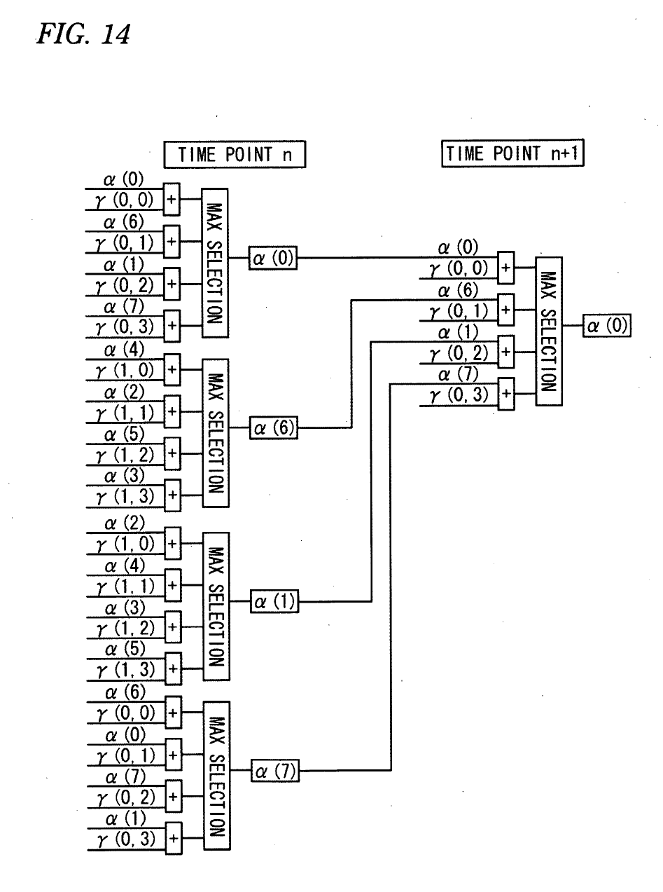

In α metric and/or β metric computation, the computation time may be reduced by performing two processes in a time sequence at one time. FIG. 14 is a diagram for explaining a method for performing two processes at one time in α metric computation.

A description will be given below with a focus on α(0). It will be apparent to those skilled in the art that the same applies to α metrics other than α(0). FIG. 14 illustrates a computation of α(0), α(6), α(1), and α(7) at time point n in a time sequence and a computation of α(0) at time point n+1.

α(0) at time point n is obtained by adding α(0) and γ(0,0) at time point n−1, adding α(6) and γ(0,1) at time point n−1, adding α(1) and γ(0,2) at time point n−1, adding α(7) and γ(0,3) at time point n−1, and selecting a maximum sum (MAX selection) of the sums. The same applies to α(6), α(1), and α(7) at time point n.

α(0) at time point n+1 is obtained by adding α(0) and γ(0,0) at time point n, adding α(6) and γ(0,1) at time point n, adding α(1) and γ(0,2) at time point n, adding α(7) and γ(0,3) at time point n, and selecting a maximum sum (MAX selection) of the sums. As described above, an α metric at time point n+1 is obtained from α metrics and a state transition probability γ at time point n−1 by two processes.

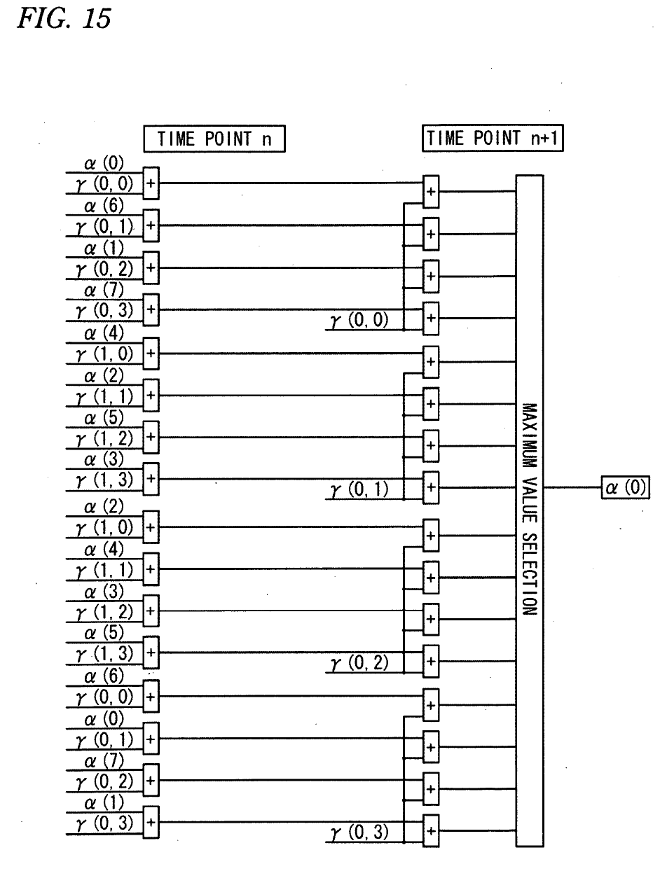

FIG. 15 is a diagram obtained by rearranging the configuration illustrated in FIG. 14. The configuration illustrated in FIG. 14 and the configuration illustrated in FIG. 15 are equivalent to each other. In FIG. 15, an α metric at time point n+1 (α(0) in FIG. 15) is obtained from α metrics and a state transition probability γ at time point n−1 and a state transition probability γ at time point n.

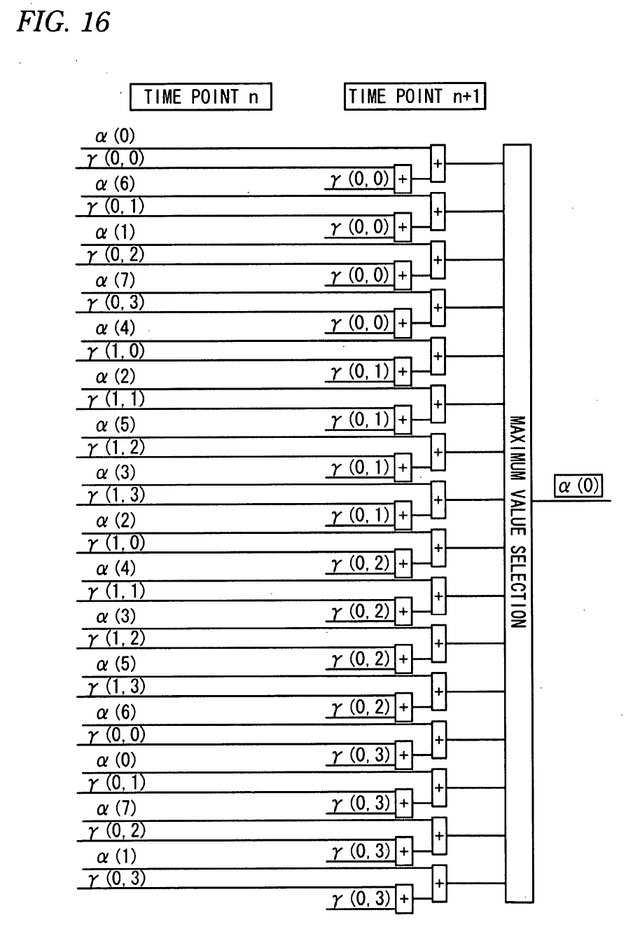

FIG. 16 is a diagram obtained by further rearranging the configuration illustrated in FIG. 15. In FIG. 15, for example, after α(0) and γ(0,0) at time point n−1 are added, γ(0,0) at time point n is added to the sum. FIG. 16 is different from FIG. 15 in that the sum of γ(0,0) at time point n−1 and γ(0,0) at time point n−1 is added to α(0) at time point n−1 but is equivalent in configuration to FIG. 15.

Addition of α and γ requires one clock, and maximum value selection of 1 out of 16 requires four clocks. The number of clocks required for the computation in FIG. 16 is thus five in total. Since three clocks are required to perform one process in a conventional method, six (=3×2) clocks are required to perform two processes. Accordingly, one clock may be saved by performing two processes at one time.

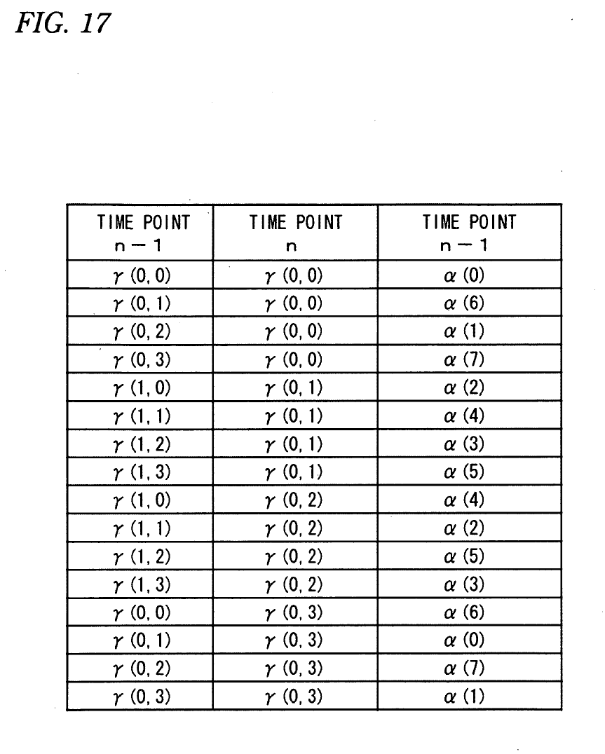

When FIG. 16 is put into a table, the table becomes as illustrated in FIG. 17.

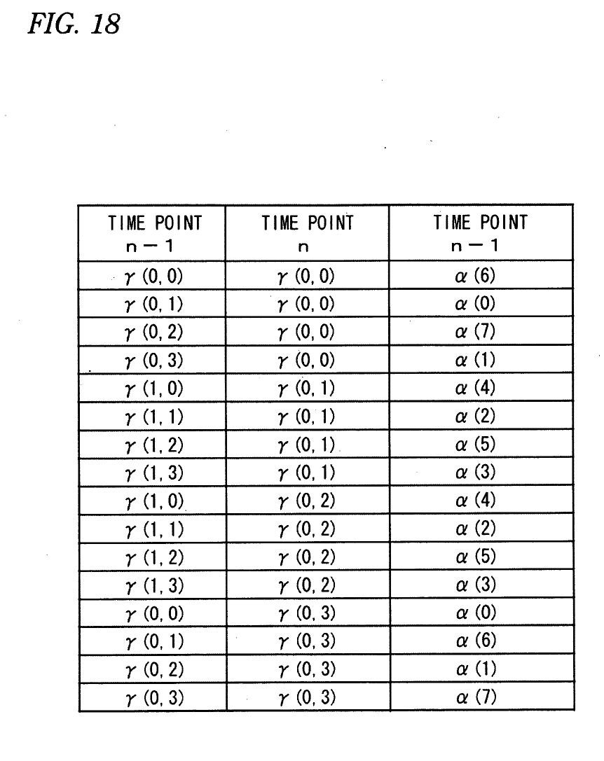

In order to obtain α(0) at time point n+1, elements in each row of the table in FIG. 18 are added and a maximum sum is selected.

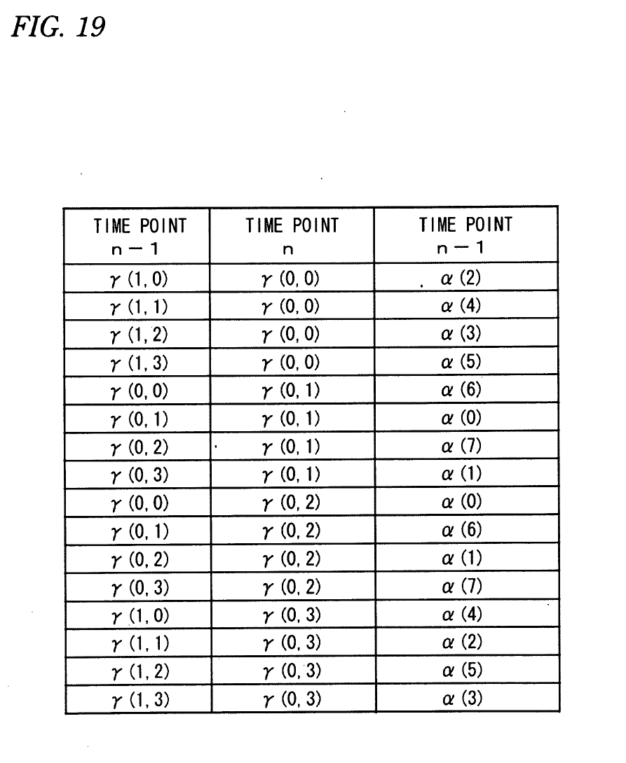

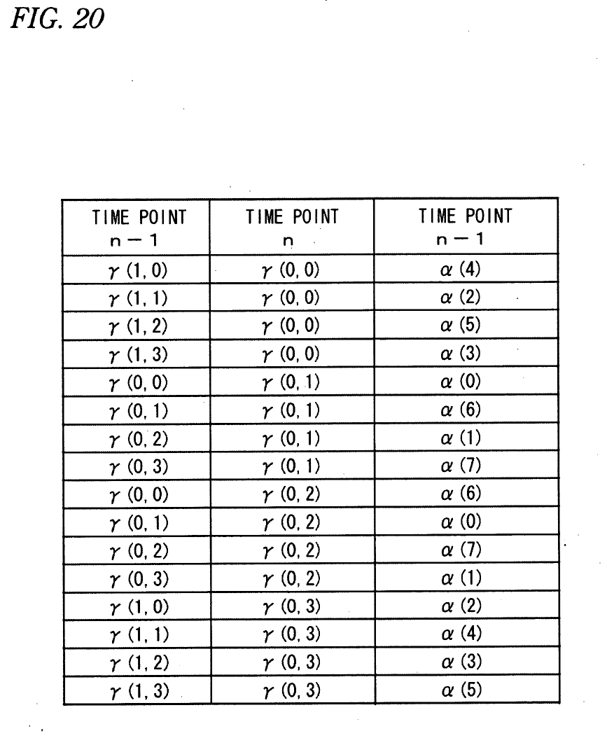

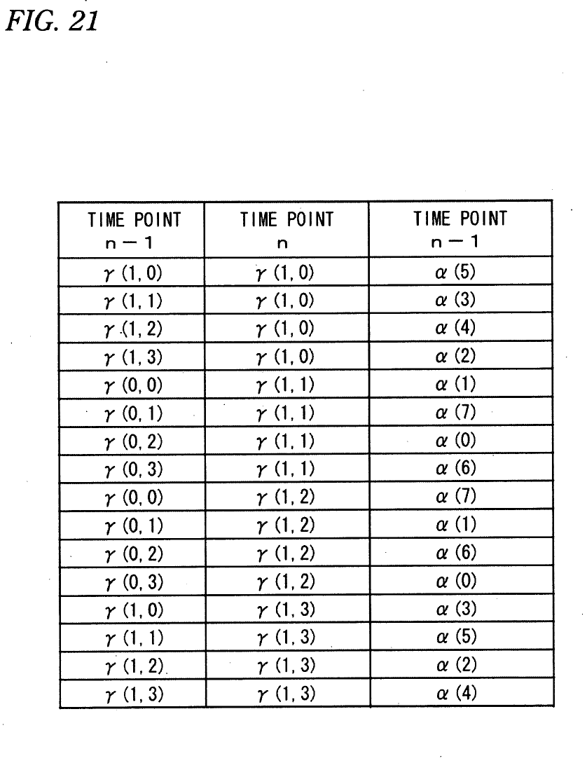

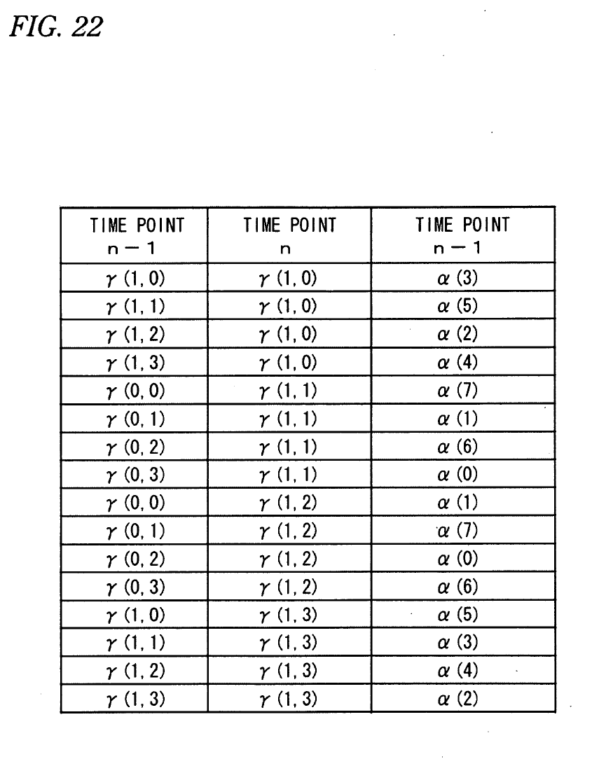

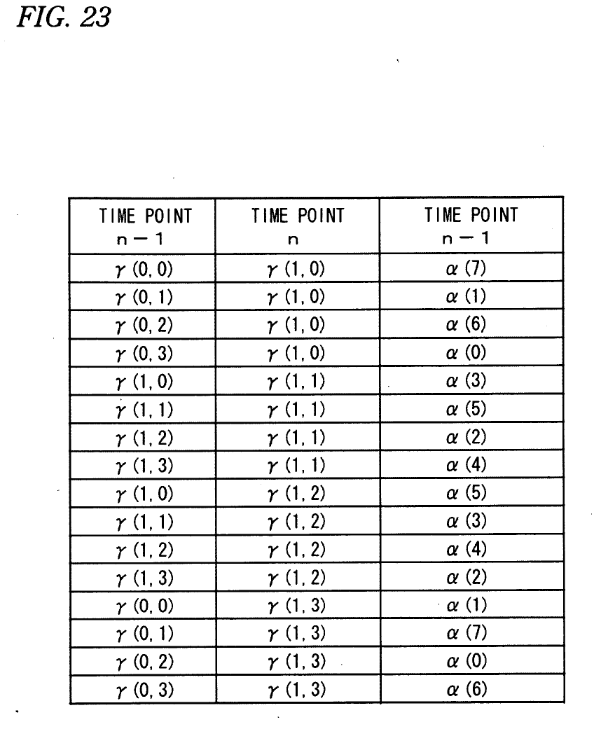

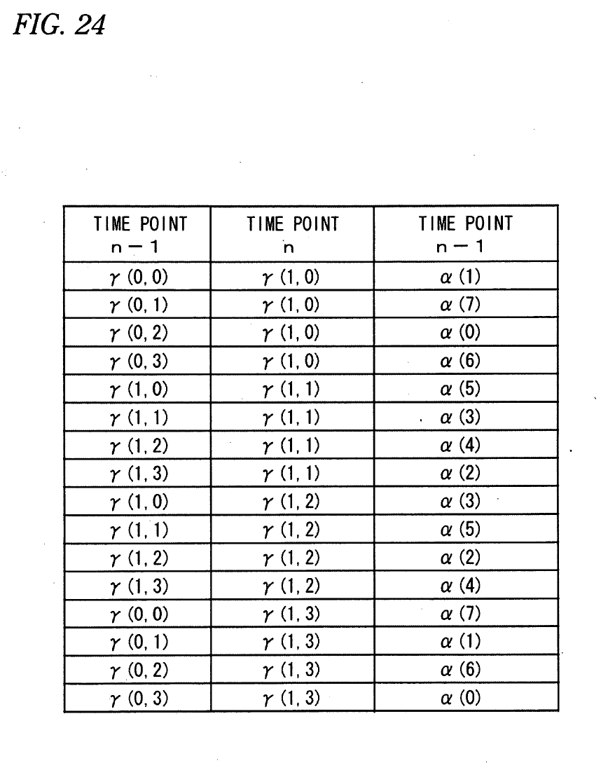

The same applies to α(1) to α(7). When elements to be added in each case are put into a table, for reference, the tables become as illustrated in FIGS. 18 to 24.

α(0) and α(3) share common γ additions whose results are to be inputted, α(4) and α(7) share common γ additions whose results are to be inputted, α(1) and α(2) share common γ additions whose results are to be inputted, and α(5) and α(6) share common γ additions whose results are to be inputted. Each set includes 16 additions. Thus, performing 64 (=16×4) additions is sufficient.

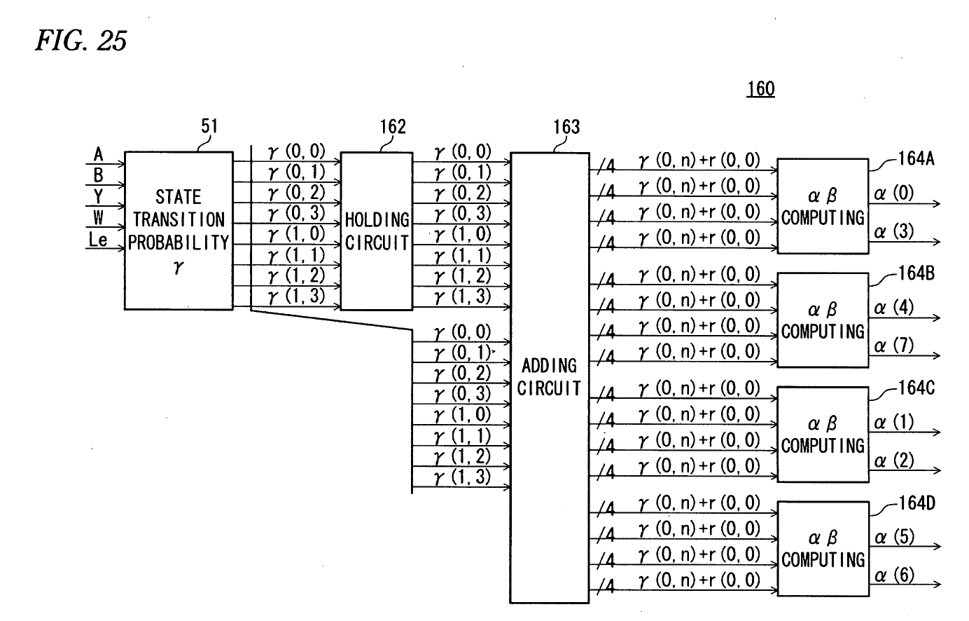

α metric computation described with reference to FIG. 16 may be implemented by circuitry as in FIG. 25. FIG. 25 is a block diagram illustrating circuitry which performs two α metric processes at one time according to an embodiment.

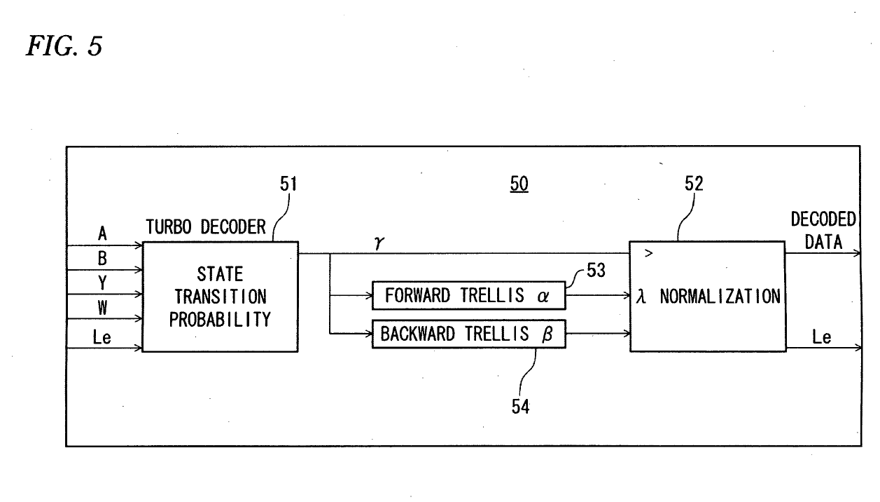

Circuitry 160 illustrated in FIG. 25 includes a state transition probability computing unit 51, a holding circuit 162, an adding circuit 163, and αβ computing units 164A to 164D. The state transition probability computing unit 51 is the state transition probability computing unit 51 illustrated in FIG. 5. As known from a comparison with the configuration illustrated in FIG. 16, the holding circuit 162 holds values of state transition probability elements γ(0,0) to γ(1,3) obtained by the state transition probability computing unit 51 at time point n−1 in the time sequence and passes the held values to the adding circuit 163 at the time of computation of α metrics at time point n+1. The state transition probability computing unit 51 also directly passes values of the state transition probability elements γ(0,0) to γ(1,3) obtained at time point n to the adding circuit 163. The adding circuit 163 adds the γ values at time point n−1 and the γ values at time point n and passes the sums to the αβ computing units 164A to 164D. The αβ computing units 164A to 164D add the γ added values received from the adding circuit 163 (e.g., computation of α(0) and α(3), the sum of γ(0,n) and γ(0,0), the sum of γ(1,n) and γ(0,1), the sum of γ(1,n) and γ(0,2), and the sum of γ(0,n) and γ(0,3); n=0 to 4) and α metrics at time point n−1 (not illustrated) and obtain maximum values, thereby obtaining α metrics at time point n+1. The αβ computing units 164A to 164D transmit the obtained α metrics at time point n+1 to a λ normalization unit (see FIG. 5).

As has been described above, a reduction in the number of clocks for α value computation makes it possible to reduce the time required for turbo code decoding.

α metric computation has been described in the context of a reduction in computation time. However, it will be apparent to those skilled in the art that the same method may be applied to β metric computation. In consideration of this, the components 164A to 164D, which compute α metrics, are referred to as αβ computing units in FIG. 25.

α metric computation has been described on the assumption that two processes are performed at one time. It is also possible to achieve a more significant time-saving effect by performing three or more processes at one time although this requires more complicated circuitry.

As for the design of a semiconductor integrated circuit, if the computation time for α metrics may not be reduced, an extra module for α metric computation is required. A reduction in computation time has the effect of eliminating the need for an extra module and allowing use of a region where such an extra module would otherwise be formed for other applications.

### <Reduction in Amount of β Memory>

As described with reference to FIG. 13, in a turbo decoder, addition of α metrics and β metrics at the same time point in a time sequence is implemented by performing computation of β metrics in descending order in advance, storing the results in a memory, and reading out the β metrics from the memory in ascending order concurrently with computation of α metrics in ascending order.

Consider the meaning of a β metric. For any of eight states of β metrics, computation leading to convergence to a maximum value indicated by γ is performed. In other words, for any state, only a maximum value remains and is accumulated upon each trellis transition. That is, a β metric approaches a cumulatively added value of a γ maximum value as a reference. Based on this insight, a β metric (β value) and a value of “a cumulatively added value of a γ maximum value minus the β metric” were obtained by simulation. After a million random trials, a maximum β metric value was 553,796 while a value of “a cumulatively added value of a γ maximum value minus the β metric” was 2,258. Although these values, of course, depend on the number of input bits and the number of repetitions, at least the former value is a 20-bit value, and the latter value is a 12-bit value. This is noteworthy from a memory-saving standpoint.

For example, if a maximum value at each time point in a time sequence is used as a reference, maximum values, the number of which corresponds to a time length, may need to be recorded. In contrast, a cumulatively added value for γ may be immediately computed without recording in a memory, as will be described below. This allows use of a 12-bit memory instead of a 20-bit memory.

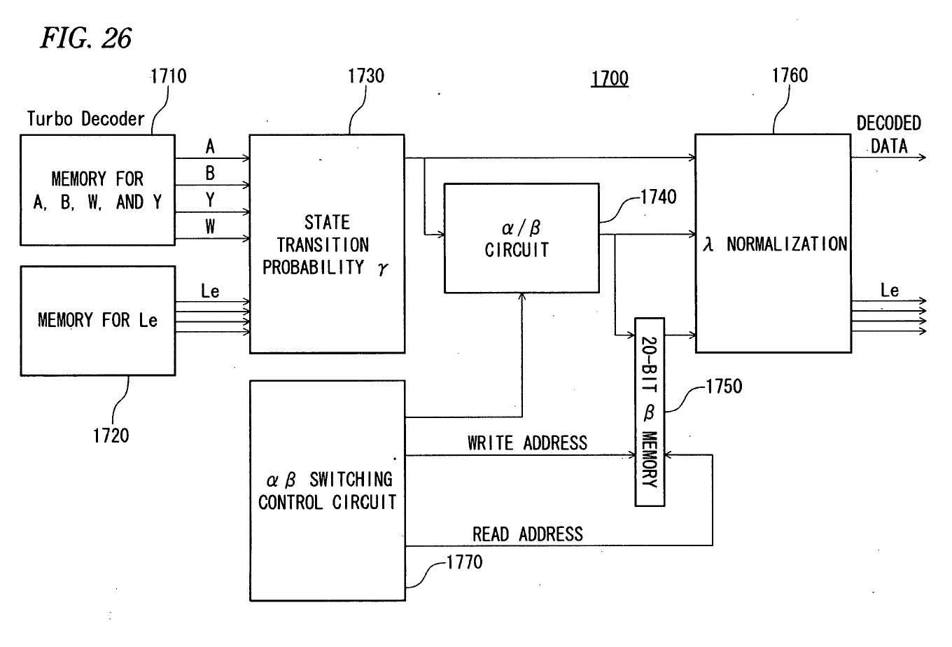

Before describing a memory for β metrics and peripheral circuits according to an embodiment, a memory for β metrics and peripheral circuits according to the related art will first be described. FIG. 26 is a diagram illustrating a single turbo decoder including a memory for β metrics and peripheral circuits according to the related art. A turbo decoder 1700 illustrated in FIG. 26 has a memory 1710, a memory 1720, a state transition probability computing unit 1730, an α/β circuit 1740, a 20-bit β memory 1750, and a λ normalization unit 1760. The memory 1710 stores inputted data A and B and flags W and Y. The memory 1720 stores a priori probability Le. The state transition probability computing unit 1730 computes a state transition probability γ based on the pieces of data stored in the memories 1710 and 1720. The α/β circuit 1740 computes α metrics and β metrics based on the state transition probability obtained by the state transition probability computing unit 1730 and the like. The 20-bit β memory 1750 stores the β metrics in descending order obtained by the α/β circuit 1740 and allows readout of the β metrics in ascending order. The λ normalization unit 1760 obtains decoded data and the priori probability Le from the state transition probability γ obtained by the state transition probability computing unit 1730, the α metrics obtained by the α/β circuit 1740, and the β metrics stored in the β memory and read out in ascending order. The priori probability Le obtained by the λ normalization unit 1760 is stored in the memory 1720 for Le. The turbo decoder 1700 further has an αβ switching control circuit 1770. The αβ switching control circuit 1770 transmits a control signal to the α/β circuit 1740 and switches the α/β circuit 1740 between α metric computation and β metric computation. The αβ switching control circuit 1770 also transmits a write address to the β memory 1750 and causes the β memory 1750 to store the β metrics computed in descending order by the α/β circuit 1740. Additionally, the αβ switching control circuit 1770 transmits a read address to the β memory 1750, reads out the β metrics stored in the β memory 1750 in ascending order, and transmits the β metrics to the λ normalization unit.

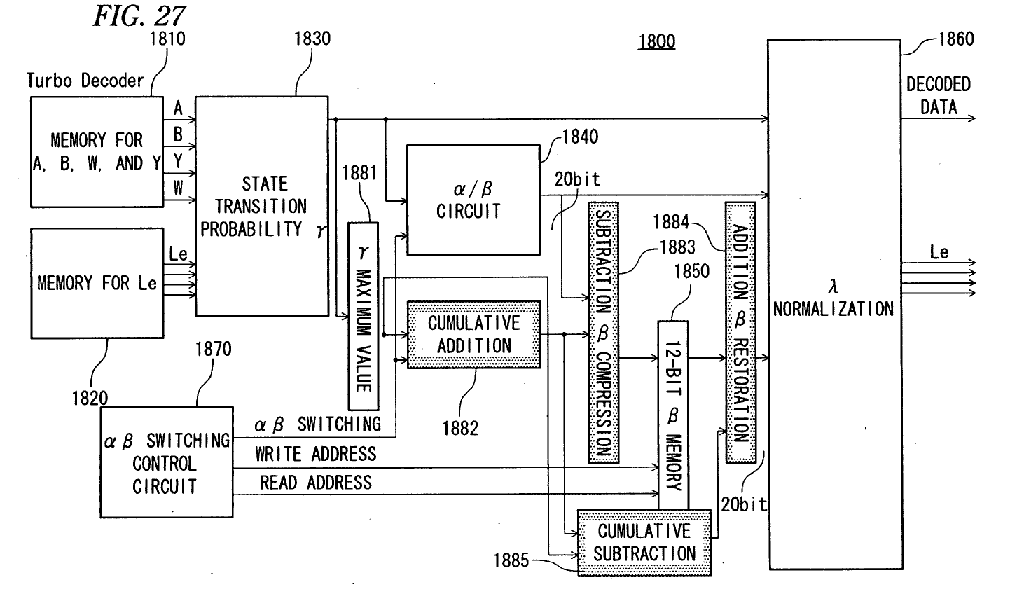

A single turbo decoder including a memory for β metrics and peripheral circuits according to an embodiment will be described. FIG. 27 is a block diagram illustrating the single turbo decoder including the memory for β metrics and the peripheral circuits according to an embodiment. A turbo decoder 1800 illustrated in FIG. 27 has a memory 1810 which stores inputted data A and B and flags W and Y, a memory 1820 which stores a priori probability Le, a state transition probability computing unit 1830 which computes a state transition probability γ based on the pieces of data stored in the memories 1810 and 1820, and an α/β circuit 1840 which computes α metrics and β metrics based on the state transition probability obtained by the state transition probability computing unit 1830 and the like. The turbo decoder 1800 further has a γ maximum value unit 1881 which obtains a maximum value of γ values obtained by the state transition probability computing unit 1830, a cumulative addition unit 1882 which cumulatively adds the maximum values, and a subtraction β compression unit 1883 which subtracts each β value obtained by the α/β circuit 1840 from a cumulatively added value obtained by the cumulative addition unit 1882. With this configuration, the single turbo decoder 1800 according to an embodiment obtains a value of “the cumulatively added value of a γ maximum value minus each β metric” and stores the value in a 12-bit β memory 1850. Compared to the β memory 1750 of the conventional turbo decoder 1700 illustrated in FIG. 26, which is 20-bits wide, the β memory 1850 of the turbo decoder 1800 according to the embodiment illustrated in FIG. 27 may be configured to be 12-bits wide, and an area required for memory formation may be reduced.

However, a value to be inputted to a λ normalization unit 1860 is a β value. Accordingly, an addition β restoration unit 1884 may reconstruct each β metric using the value of “the cumulatively added value of a γ maximum value minus the β metric” stored in the β memory 1850 together with a result of subjecting the γ maximum value obtained by the γ maximum value unit 1881 to cumulative subtraction in a cumulative subtraction unit 1885. The addition β restoration unit 1884 transmits a restored 20-bit β value to the λ normalization unit 1860. The λ normalization unit 1860 obtains decoded data and a priori probability Le from the state transition probability γ obtained by the state transition probability computing unit 1830, the α metrics obtained by the α/β circuit 1840, and the β metrics restored by the addition β restoration unit 1884. The priori probability Le obtained by the λ normalization unit 1860 is stored in the memory 1820 for Le. The turbo decoder 1800 further has an αβ switching control circuit 1870. The αβ switching control circuit 1870 transmits a control signal to the α/β circuit 1840 and switches the α/β circuit 1840 between α metric computation and β metric computation. The αβ switching control circuit 1870 also transmits a write address to the 12-bit β memory 1850 and causes the β memory 1850 to store a result of compression in the subtraction β compression unit 1883 (“a cumulatively added value of a γ maximum value minus a β metric”). Additionally, the αβ switching control circuit 1870 transmits a read address to the β memory 1850 and causes a β metric restored by the addition β restoration unit 1884 to be transmitted to the λ normalization unit 1860.

In the case of β computation, letting n be the number of pieces of data, the accumulative addition unit 1882 has a cumulatively added value of γ maximum values for pieces of data numbered n−1 to 0. When α computation is started after β computation, β values are required in order from the piece of data numbered 0. For example, if the accumulative subtraction unit 1885 performs cumulative subtraction to obtain, for the piece of data numbered 0, a final cumulatively added value; for the piece of data numbered 1, a value obtained by subtracting the γ maximum value for the piece of data numbered 0 from the final cumulatively added value; for the piece of data numbered 2, a value obtained by subtracting the γ maximum value for the piece of data numbered 1 from the value for the piece of data numbered 1; and so on, it is possible to restore each β value without storing a cumulatively added value for each of the n pieces of data.

As has been described above, the turbo decoder according to the embodiment may reduce the amount of memory (β memory) required for turbo code decoding.

### <Reduction in Amount of α Memory>

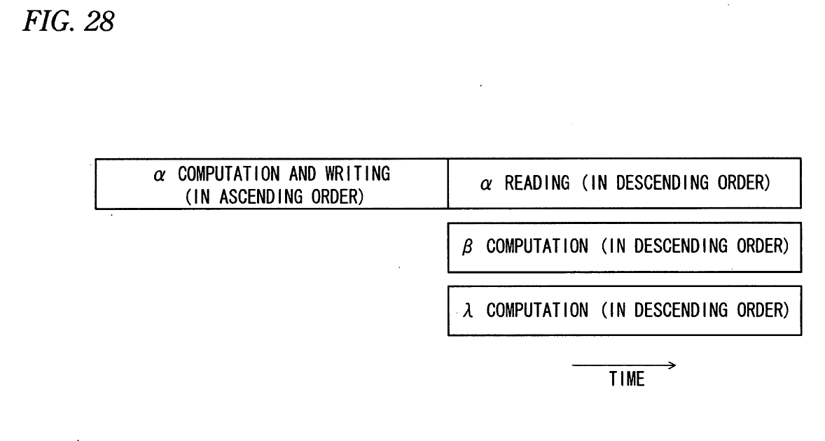

The above description assumes that computation of β metrics in descending order is performed in advance, the results are stored in the memory, and the β metrics are read out in ascending order at the time of α metric computation. As illustrated in FIG. 28, the turbo decoder may perform computation of α metric in ascending order in advance, store the results in a memory, and read out the α metrics in descending order at the time of β metric computation. This allows for the addition of α metrics and β metrics at the same time point in a time sequence.

In this case as well, each α value is computed to converge to a maximum value indicated by γ. In other words, for any state, only a maximum value remains and is accumulated upon each trellis transition.

An α metric (α value) and a value of “a cumulatively added value of a γ maximum value minus the α metric” were obtained by simulation. After a million random trials, a maximum α value was 553,796 while a value of “a cumulatively added value of a γ maximum value minus the α metric” was 2,258. Although these values depend on the number of input bits and the number of repetitions, at least the former value is a 20-bit value, and the latter value is a 12-bit value. This is noteworthy from a memory-saving standpoint.

For example, if a maximum value at each time point in a time sequence is used as a reference, maximum values, the number of which corresponds to a time length, may need to be recorded. In contrast, a cumulatively added value for γ may be immediately computed without recording in a memory, as will be described below. This allows for the use of a 12-bit memory instead of a 20-bit memory.

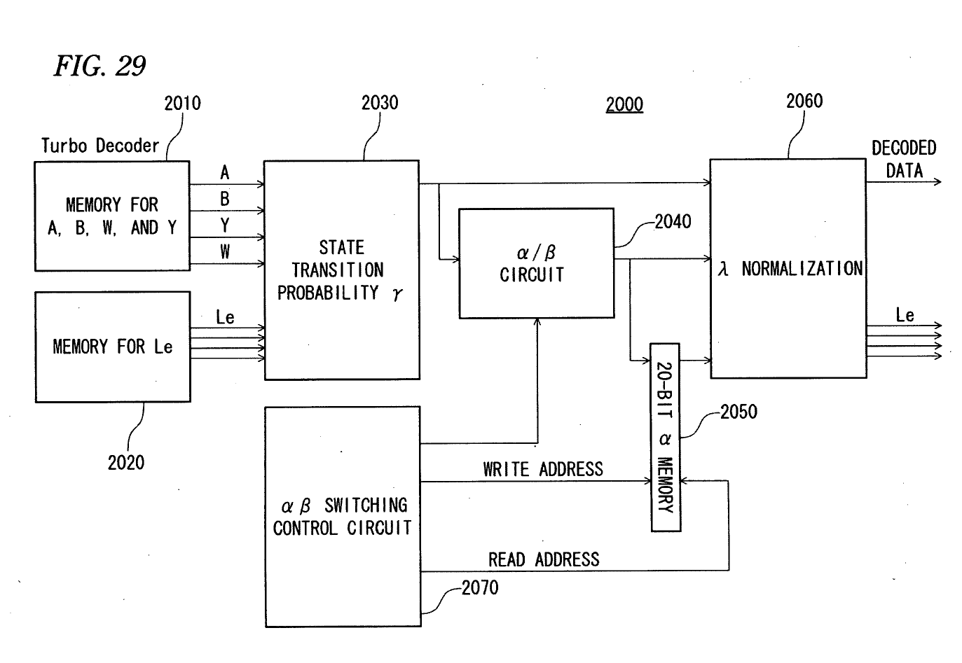

In order to describe a memory for α metrics and peripheral circuits according to an embodiment, a memory for α metrics and peripheral circuits according to the related art will first be described. FIG. 29 is a diagram illustrating a single turbo decoder including a memory for α metrics and peripheral circuits according to the related art. A turbo decoder 2000 illustrated in FIG. 29 has a memory 2010, a memory 2020, a state transition probability computing unit 2030, an α/β circuit 2040, a 20-bit α memory 2050, and a λ normalization unit 2060. The memory 2010 stores inputted data A and B and flags W and Y. The memory 2020 stores a priori probability Le. The state transition probability computing unit 2030 computes a state transition probability γ based on the pieces of data stored in the memories 2010 and 2020. The α/β circuit 2040 computes α metrics and β metrics based on the state transition probability obtained by the state transition probability computing unit 2030 and the like. The 20-bit α memory 2050 stores the α metrics in ascending order obtained by the α/β circuit 2040 and allows readout of the α metrics in descending order. The λ normalization unit 2060 obtains decoded data and the priori probability Le from the state transition probability γ obtained by the state transition probability computing unit 2030, the β metrics obtained by the α/β circuit 2040, and the α metrics stored in the α memory and read out in descending order. The priori probability Le obtained by the λ normalization unit 2060 is stored in the memory 2020 for Le. The turbo decoder 2000 further has an αβ switching control circuit 2070. The αβ switching control circuit 2070 transmits a control signal to the α/β circuit 2040 and switches the α/β circuit 2040 between α metric computation and β metric computation. The αβ switching control circuit 2070 also transmits a write address to the α memory 2050 and causes the α memory 2050 to store the α metrics computed in ascending order by the α/β circuit 2040. Additionally, the αβ switching control circuit 2070 transmits a read address to the α memory 2050, reads out the α metrics stored in the α memory 2050 in descending order, and transmits the α metrics to the λ normalization unit 2060.

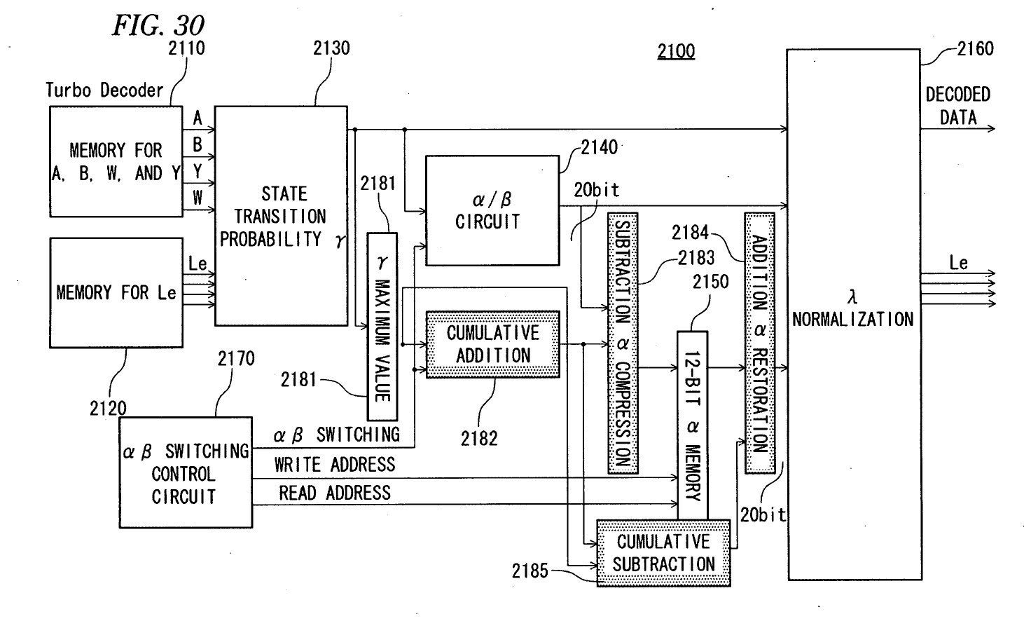

A single turbo decoder including a memory for α metrics and peripheral circuits thereto according to an embodiment will be described. FIG. 30 is a block diagram illustrating the single turbo decoder including the memory for α metrics and the peripheral circuits according to an embodiment. A turbo decoder 2100 illustrated in FIG. 30 has a memory 2110 which stores inputted data A and B and flags W and Y, a memory 2120 which stores a priori probability Le, a state transition probability computing unit 2130 which computes a state transition probability γ based on the pieces of data stored in the memories 2110 and 2120, and an α/β circuit 2140 which computes α metrics and β metrics based on the state transition probability obtained by the state transition probability computing unit 2130, and the like. The turbo decoder 2100 further has a γ maximum value unit 2181 which obtains a maximum one of γ values obtained by the state transition probability computing unit 2130, a cumulative addition unit 2182 which cumulatively adds the maximum values, and a subtraction α compression unit 2183 which subtracts each α value obtained by the α/β circuit 2140 from a cumulatively added value obtained by the cumulative addition unit 2182. With this configuration, the single turbo decoder 2100 according to the embodiment obtains a value of “the cumulatively added value of a γ maximum value minus each α metric” and stores the value in a 12-bit α memory 2150. Compared to the α memory 2050 of the conventional turbo decoder 2000 illustrated in FIG. 29, which is 20-bits wide, the α memory 2150 of the turbo decoder 2100 according to the embodiment illustrated in FIG. 30 may be configured to be 12-bits wide, and an area required for memory formation may be reduced.

However, a value to be inputted to a λ normalization unit 2160 is an α value. Accordingly, an addition α restoration unit 2184 may reconstruct each α metric using the value of “the cumulatively added value of a γ maximum value minus the α metric” stored in the α memory 2150 together with a result of subjecting the γ maximum value obtained by the γ maximum value unit 2181 to cumulative subtraction in a cumulative subtraction unit 2185. The addition α restoration unit 2184 transmits a restored 20-bit α value to the λ normalization unit 2160. The λ normalization unit 2160 obtains decoded data and a priori probability Le from the state transition probability γ obtained by the state transition probability computing unit 2130, the β metrics obtained by the α/β circuit 2140, and the α metrics restored by the addition α restoration unit 2184. The priori probability Le obtained by the λ normalization unit 2160 is stored in the memory 2120 for Le. The turbo decoder 2100 further has an αβ switching control circuit 2170. The αβ switching control circuit 2170 transmits a control signal to the α/β circuit 2140 and switches the α/β circuit 2140 between α metric computation and β metric computation. The αβ switching control circuit 2170 also transmits a write address to the 12-bit α memory 2150 and causes the α memory 2150 to store a result of compression in the subtraction α compression unit 2183 (“a cumulatively added value of a γ maximum value minus an α metric”). Additionally, the αβ switching control circuit 2170 transmits a read address to the α memory 2150 and causes an α metric restored by the addition α restoration unit 2184 to be transmitted to the λ normalization unit 2160.

In the case of α computation, letting n be the number of pieces of data, the accumulative addition unit 2182 has a cumulatively added value of γ maximum values for pieces of data numbered n−1 to 0. When β computation is started after α computation, α values are required in order from the piece of data numbered n−1. For example, if the accumulative subtraction unit 2185 performs cumulative subtraction to obtain, for the piece of data numbered n−1, a final cumulatively added value; for the piece of data numbered n−2, a value obtained by subtracting the γ maximum value for the piece of data numbered n−1 from the final cumulatively added value; for the piece of data numbered n−3, a value obtained by subtracting the γ maximum value for the piece of data numbered n−2 from the value for the piece of data numbered n−2; and so on, it is possible to restore each α value without storing a cumulatively added value for each piece of data.

As has been described above, the turbo decoder according to the embodiment may reduce the amount of memory (α memory) required for turbo code decoding.

### <Method Without Addition Restoration of α and β>

A method of subjecting a β value (or an α value) to subtraction compression and storing the resultant value in a memory and subjecting the value to addition restoration at the time of passing the value to a λ normalization unit has been described above. However, both an α value and a β value may be subjected to subtraction compression and be passed to the λ normalization unit without addition restoration. In this case, λ maximum value selection may be first performed, and a cumulative value may be added at the time of computation of a priori probability Le.

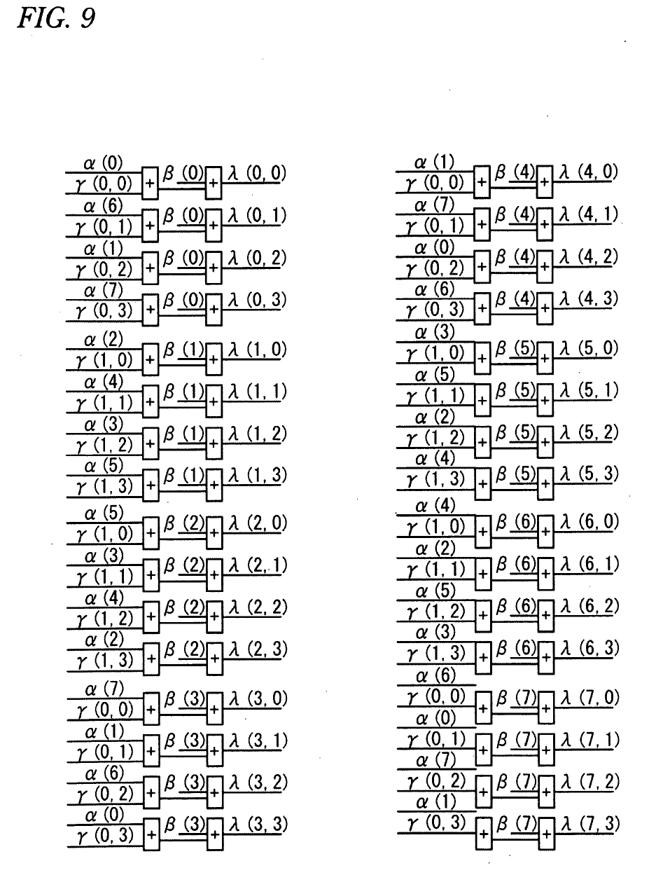

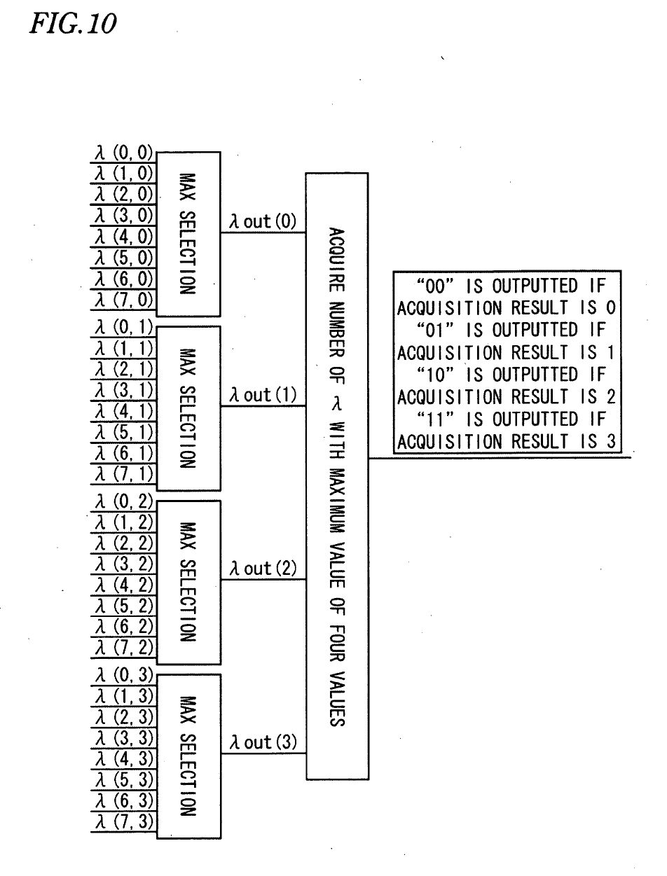

This is due to the following reason. As illustrated in FIGS. 9 and 10, λ maximum value selection is performed after α values and β values are added. Since only a maximum value selection is performed, even if a constant value is subtracted both from each α value and each β value, the same results are obtained. Note that since a value of Le itself has a meaning and may need to be obtained, the process of adding the constant value to a selected λout value may be performed after the maximum value selection.

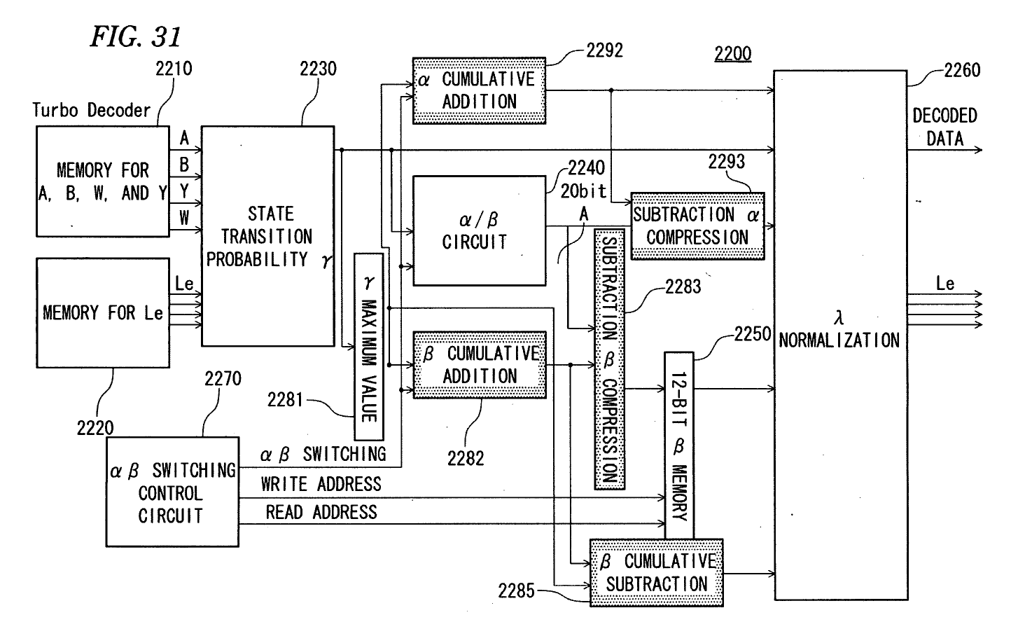

The above-described method may be implemented by circuitry as in FIG. 31. FIG. 31 is a block diagram illustrating αβ compression, a memory for β, and peripheral circuits according to one embodiment.

A single turbo decoder 2200 illustrated in FIG. 31 including αβ compression, a memory for β, and peripheral circuits according to the embodiment has a memory 2210 which stores inputted data A and B and flags W and Y, a memory 2220 which stores a priori probability Le, a state transition probability computing unit 2230 which computes a state transition probability γ based on the pieces of data stored in the memories 2210 and 2220, and an α/β circuit 2240 which computes α metrics and β metrics based on the state transition probability obtained by the state transition probability computing unit 2230, and the like. The turbo decoder 2200 further has a γ maximum value unit 2281 which obtains a maximum value of γ values obtained by the state transition probability computing unit 2230, a β cumulative addition unit 2282 which cumulatively adds the maximum value, and a subtraction β compression unit 2283 which subtracts each β value obtained by the α/β circuit 2240 from a cumulatively added value obtained by the β cumulative addition unit 2282. With this configuration, the single turbo decoder 2200 according to the embodiment obtains a value of “the cumulatively added value of a γ maximum value minus each β metric” and stores the value in a 12-bit β memory 2250. The β memory 2250 of the turbo decoder 2200 according to the embodiment illustrated in FIG. 31 may be configured to be 12-bits wide, and a region required for memory formation may be saved. The value of “the cumulatively added value of a γ maximum value minus the β metric” stored in the β memory is transmitted to a λ normalization unit 2260.

The turbo decoder 2200 further has an α cumulative addition unit 2292 which cumulatively adds the γ maximum value obtained by the γ maximum value unit 2281 and a subtraction α compression unit 2293 which subtracts each α value obtained by the α/β circuit 2240 from a cumulatively added value obtained by the cumulative addition unit 2292. With this configuration, the single turbo decoder 2200 according to the embodiment obtains a value of “the cumulatively added value of a γ maximum value minus each α metric” and transmits the value to the λ normalization unit 2260.

Note that although the α cumulative addition unit 2292 and the β cumulative addition unit 2282 are illustrated as separate blocks in FIG. 31, since α computation and β computation may not be performed at the same time, it is, in practice, possible to time-share a single circuit. The time sharing is performed in accordance with a control signal (αβ switching) from an αβ switching control circuit 2270. Similarly, although the subtraction α compression unit 2293 and the subtraction β compression unit 2283 are illustrated as separate blocks in FIG. 31, it is, in practice, possible to time-share a single circuit. The time sharing is performed in accordance with a control signal (not illustrated) from the αβ switching control circuit 2270.

The αβ switching control circuit 2270 transmits a control signal to the α/β circuit 2240 and switches the α/β circuit 2240 between α metric computation and β metric computation. The αβ switching control circuit 2270 also transmits a write address and a read address to the β memory 2250 and controls writing of data from the subtraction β compression unit 2283 and reading of data from the β memory 2250.

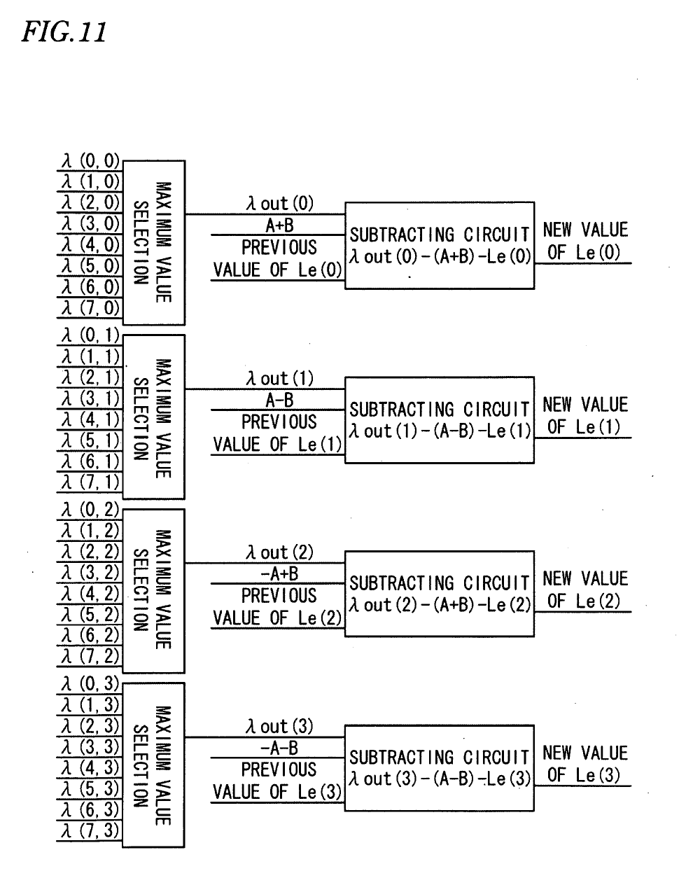

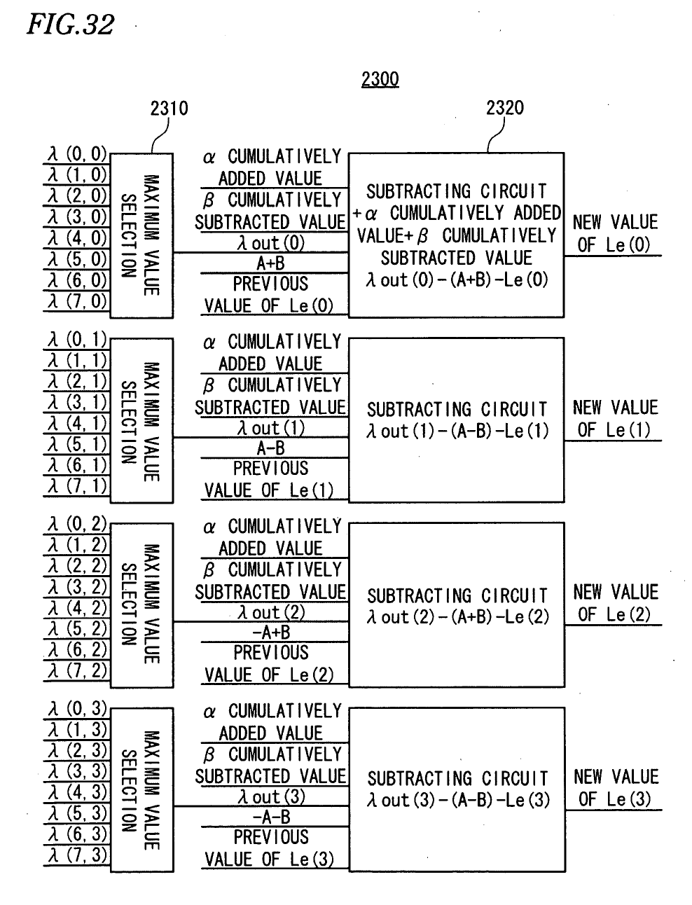

FIG. 32 is a diagram explaining an arithmetic circuit which obtains a priori probability Le when αβ compression is performed, according to an embodiment. An arithmetic circuit 2300 in FIG. 32 is a part of the λ normalization unit 2260 in FIG. 31. For example, assume a case where a new value of Le(0) is obtained. A new value of Le(0) is a value obtained by selecting a maximum one (λout(0)) of code state transition probability elements λ(0,0) to λ(7,0) (by a maximum value selecting unit 2310) and subtracting elements as A and B (A+B in the case of Le(0)) and a previous value of Le(0) from the maximum value (by a subtracting circuit 2320). The arithmetic circuit 2300 is the same as the arithmetic circuit illustrated in FIG. 11 which obtains the priori probability Le as described so far. However, the addition β restoration unit 1884 (FIG. 27) and the addition α restoration unit 2184 (FIG. 30) are absent in FIG. 31. That is, the value of λout(0) does not include an α cumulatively added value and a β cumulatively subtracted value. For this reason, as inputs to the subtracting circuit 2320, the α cumulative addition unit 2292 (FIG. 31) may input an α cumulatively added value, and the β cumulative subtraction unit 2285 (FIG. 31) may input a β cumulatively subtracted value.

As described above, the turbo decoder according to the embodiment does not additively restore a compressed α value and/or a compressed β value. Accordingly, the number of input bits to the λ arithmetic circuit may be reduced, and the numbers of bits of the addition circuits and the maximum value selecting circuits may be reduced. This allows an increase in operating speed and a reduction in circuit scale.

More specific examples will be described below.

### FIRST EXAMPLE

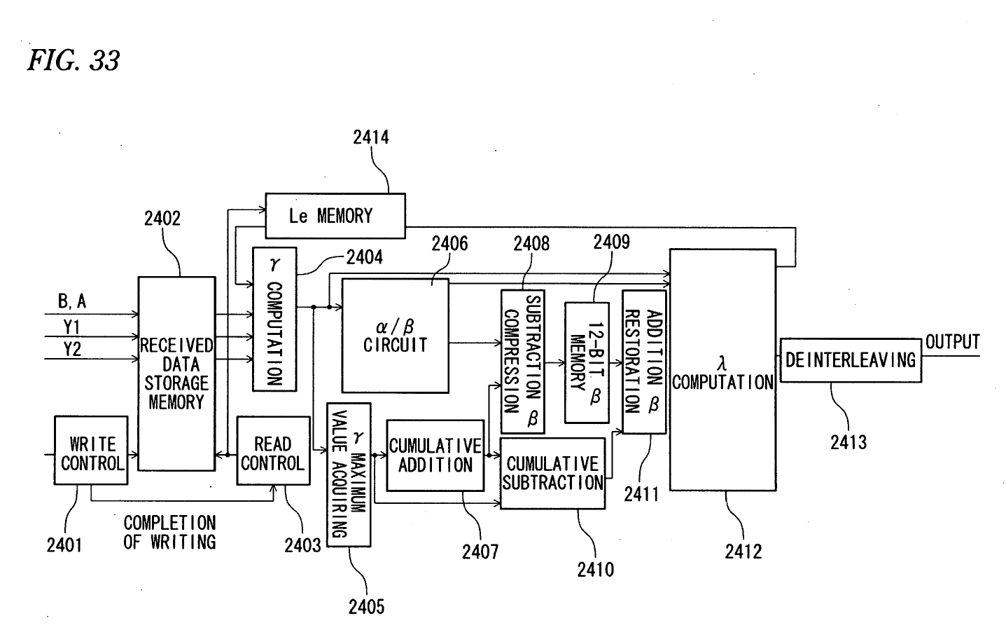

A first example is a turbo decoder in which, with use in IEEE 802.16 (WiMAX) in mind, the computation time for two αβ computations has been reduced from six clocks to five clocks, and the amount of a β memory has been reduced. FIG. 33 is a block diagram illustrating a turbo decoder according to the first example.

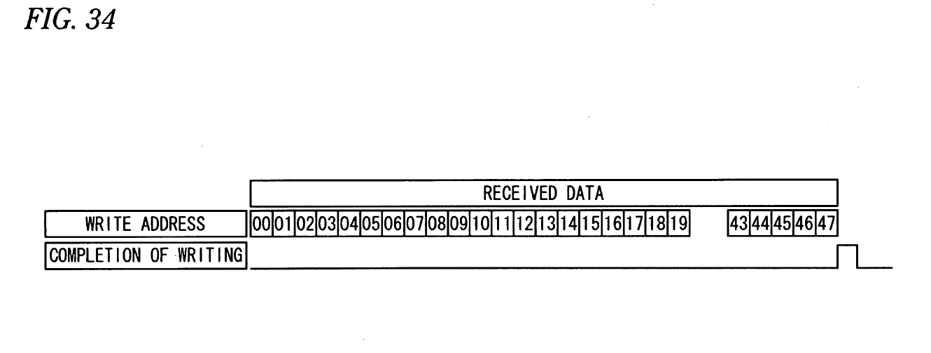

The turbo decoder receives B, A, Y1, and Y2 as received data. As each of the received data B. A, Y1, and Y2, de-grouped data and/or de-subblocked data is generally inputted. A write control unit 2401 generates control signals for writing received data (an address and a write enable signal). The received data is stored in a received data storage memory 2402. As illustrated in FIG. 34, when inputting of the received data is completed, the write control unit 2401 asserts a signal to notify a read control unit 2403 of the completion of writing, and read control is started.

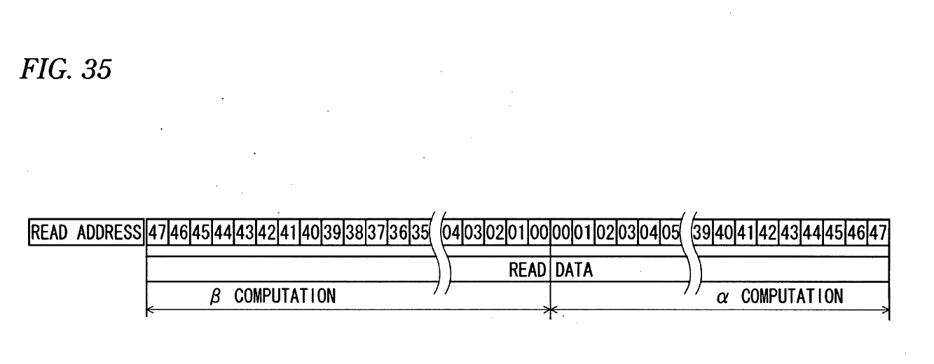

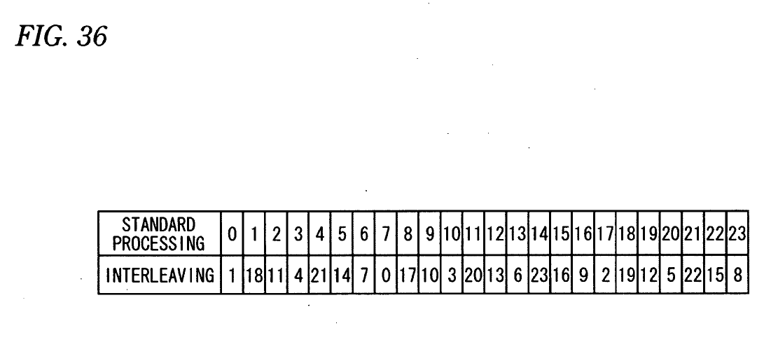

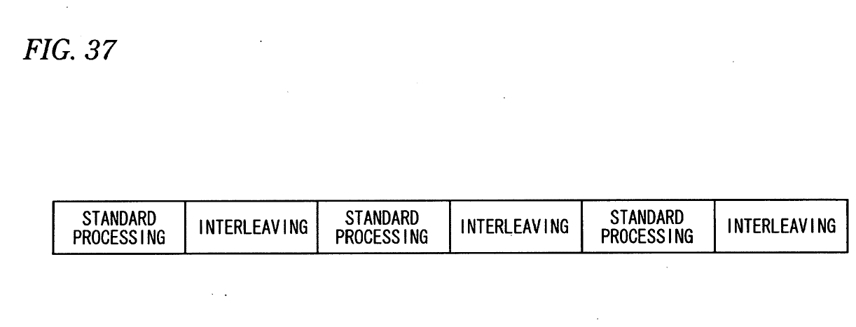

The read control unit 2403 generates a read address. In reading, pieces of data for β computation are first outputted in descending order (from address 47 to address 00), and pieces of data for α computation are then outputted in ascending order (from address 00 to address 47), as illustrated in FIG. 35. Address interleaving is performed depending on whether processing to be performed is normal processing (standard processing without interleaving) or interleaving. An interleaving system varies according to data size. For example, if the data size is 48 bits, interleaving is performed according to the interleave table illustrated in FIG. 36. Whether to perform interleaving depends on how many times the processing has been performed. When interleaving is to be performed is determined by the number of times defined by iteration. For example, if iteration=3, the processing is repeated six times in total, as illustrated in FIG. 37.

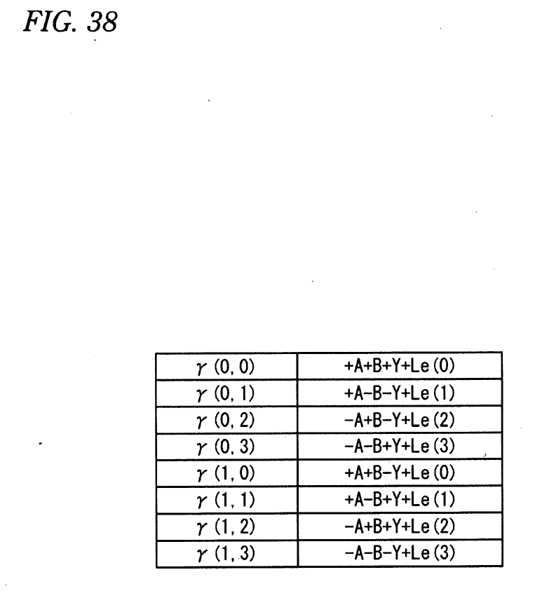

A γ computing unit 2404 performs computation determined by the configuration of an encoder. Since WiMAX does not use W1 and W2 when HARQ is not used, γ computation is substantially determined by A, B, Y1, Y2, and Le. Switching between Y1 and Y2 depends on whether standard processing or interleaving is to be performed. Y1 is selected at the time of standard processing, and Y2 is selected at the time of interleaving. The γ computing unit 2404 computes γ in the manner indicated by the γ computation correspondence table illustrated in FIG. 38 and outputs γ as a 2-by-4 array.

A γ maximum value acquiring unit 2405 obtains a maximum value of γ values outputted by the γ computing unit 2404.

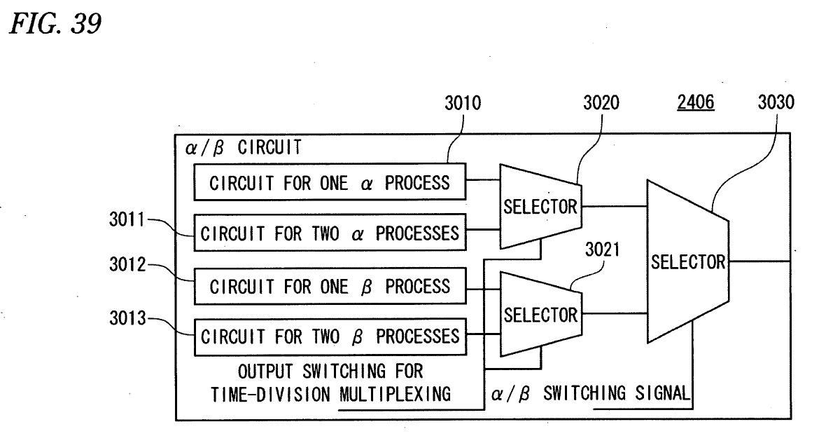

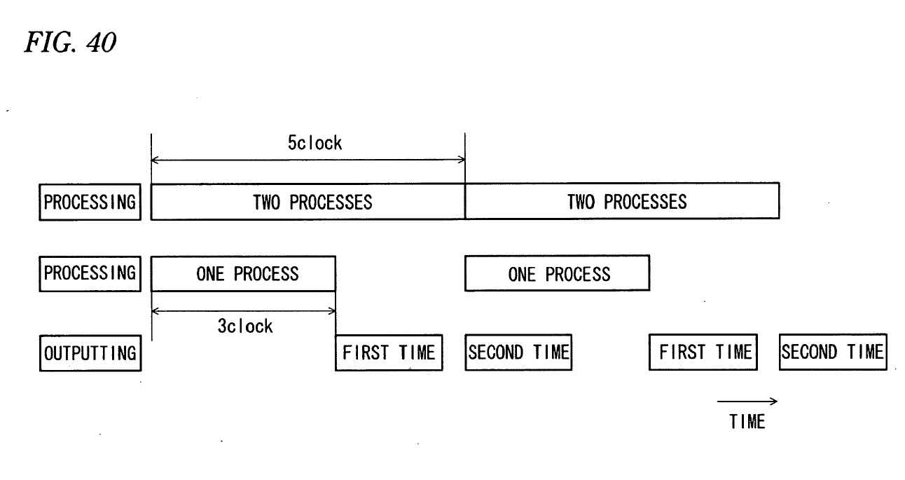

An α/β circuit 2406 is a circuit which computes α metrics and β metrics. The details of the α/β circuit 2406 is illustrated in FIG. 39. The α/β circuit illustrated in FIG. 39 has a circuit 3010 for one α process, a circuit 3011 for two α processes, a circuit 3012 for one β process, and a circuit 3013 for two β processes. In computation by each circuit, a maximum value is selected from values obtained by adding elements of a corresponding combination in the tables below. Processing results from the above-described circuits are time-division multiplexed and outputted in a manner indicated by the αβ switching processing time chart in FIG. 40 by selectors 3020, 3021, and 3030. Two α or β processes are performed in five clocks by the circuit 3011 for two α processes or circuit 3013 for two β processes. In parallel with this, one α or β process is performed in three clocks by the circuit 3010 for one α process or circuit 3012 for one β process. The selectors selectively output a result of one process and a result of two processes.

As one α process, the following may be computed:

α(0)=MAX(α(0)+γ(0,0), α(6)+γ(0,1), α(1)+γ(0,2), α(7)+γ(0,3)),

α(1)=MAX(α(2)+γ(1,0), α(4)+γ(1,1), α(3)+γ(1,2), α(5)+γ(1,3)),

α(2)=MAX(α(5)+γ(1,0), α(3)+γ(1,1), α(4)+γ(1,2), α(2)+γ(1,3)),

α(3)=MAX(α(7)+γ(0,0), α(1)+γ(0,1), α(6)+γ(0,2), α(0)+γ(0,3)),

α(4)=MAX(α(1)+γ(0,0), α(7)+γ(0,1), α(0)+γ(0,2), α(6)+γ(0,3)),

α(5)=MAX(α(3)+γ(1,0), α(5)+γ(1,1), α(2)+γ(1,2), α(4)+γ(1,3)),

α(6)=MAX(α(4)+γ(1,0), α(2)+γ(1,1), α(5)+γ(1,2), α(3)+γ(1,3)), and

α(7)=MAX(α(6)+γ(0,0), α(0)+γ(0,1), α(7)+γ(0,2), α(1)+γ(0,3)).

As two α metric processes, the process of adding all input elements described above with reference to the tables in FIGS. 17 to 24 is performed and then maximum values of the sums are selected.

As one β process, the following may be computed:

β(0)=MAX(β(0)+γ(0,0), β(7)+γ(0,1), β(4)+γ(0,2), β(3)+γ(0,3)),

β(1)=MAX(β(4)+γ(0,0), β(3)+γ(0,1), β(0)+γ(0,2),

β(7)+γ(0,3)), ·β(2)=MAX(β(1)+γ(1,0), β(6)+γ(1,1), β(5)+γ(1,2),

β(2)+γ(1,3)), ·β(3)=MAX(β(5)+γ(1,0), β(2)+γ(1,1), β(1)+γ(1,2),

β(6)+γ(1,3)), ·β(4)=MAX(β(6)+γ(1,0), β(1)+γ(1,1), β(2)+γ(1,2),

β(5)+γ(1,3)), ·β(5)=MAX(β(2)+γ(1,0), β(5)+γ(1,1), β(6)+γ(1,2),

β(1)+γ(1,3)), ·β(6)=MAX(β(7)+γ(0,0), β(0)+γ(0,1), β(3)+γ(0,2), β(4)+γ(0,3)),

and β(7)=MAX(β(3)+γ(0,0), β(4)+γ(0,1), β(7)+γ(0,2), β(0)+γ(0,3)).

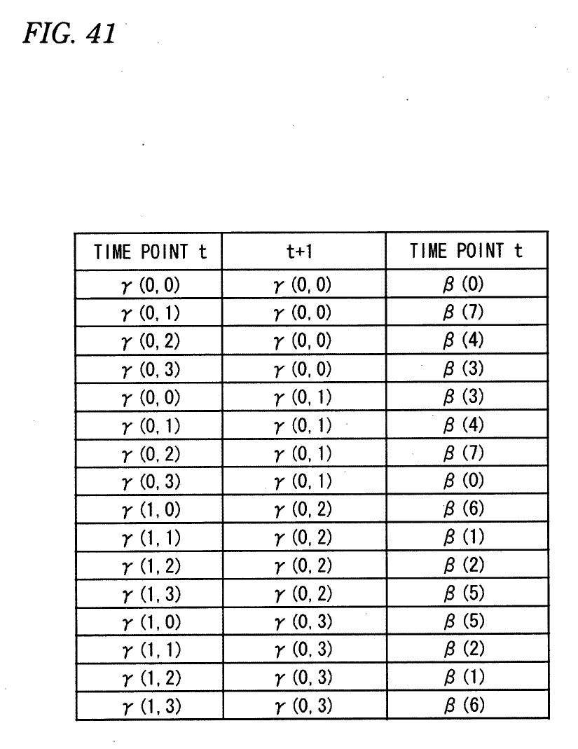

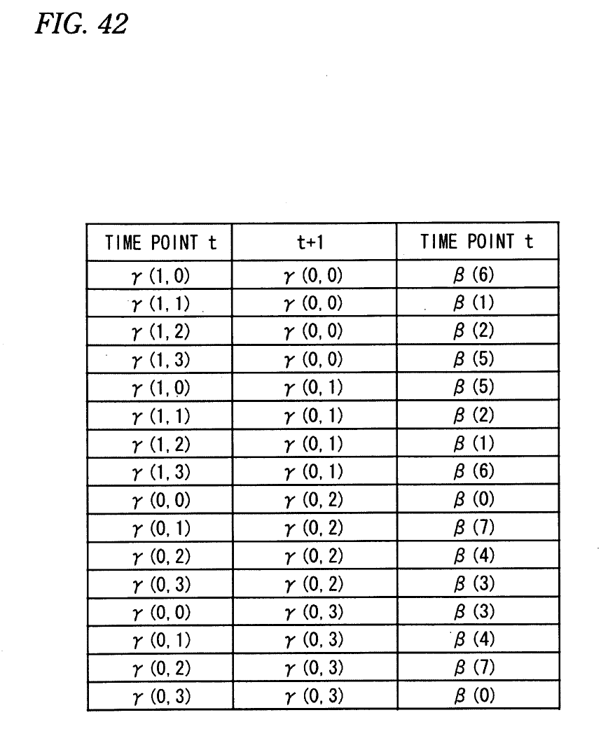

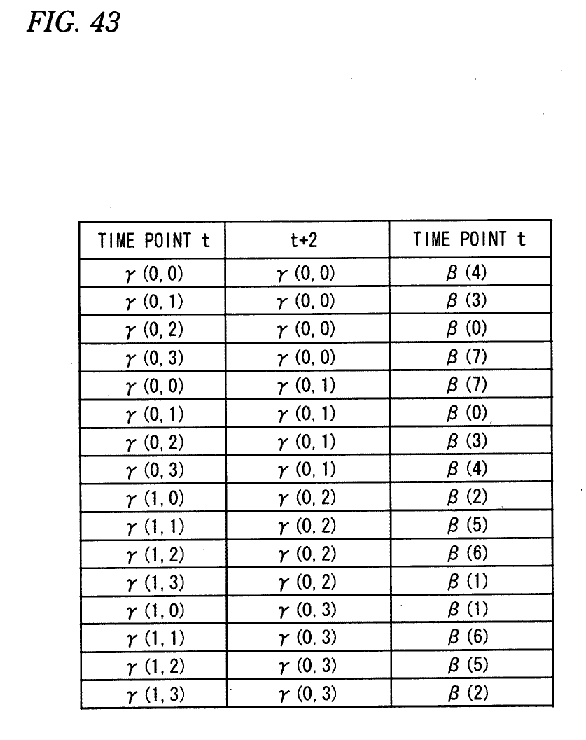

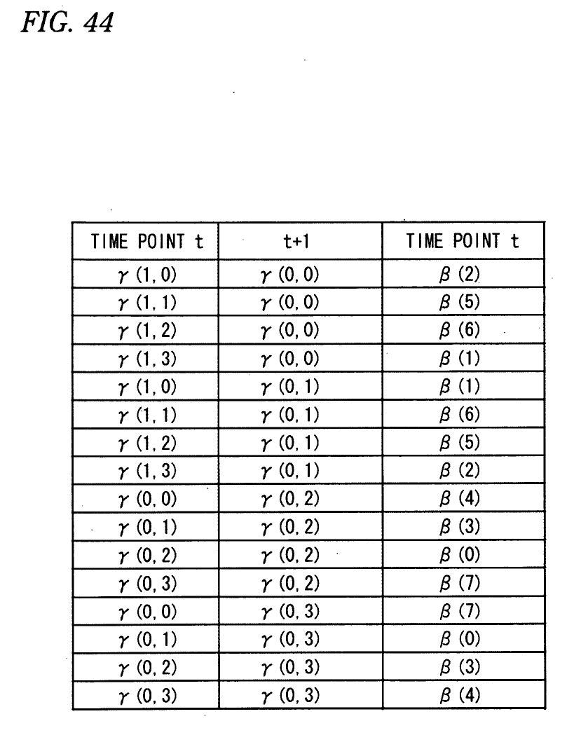

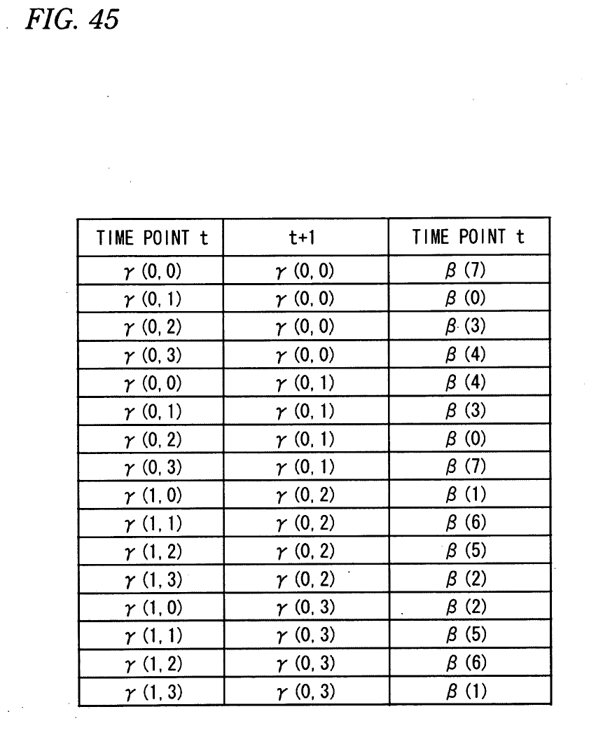

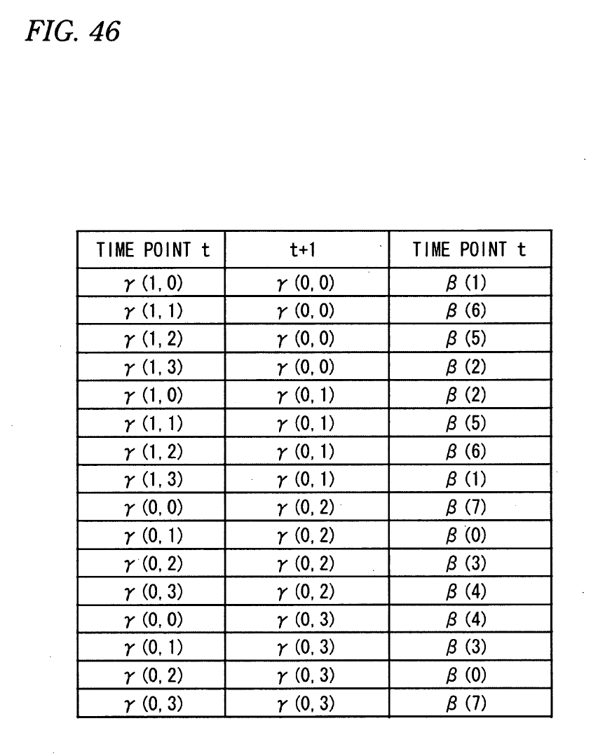

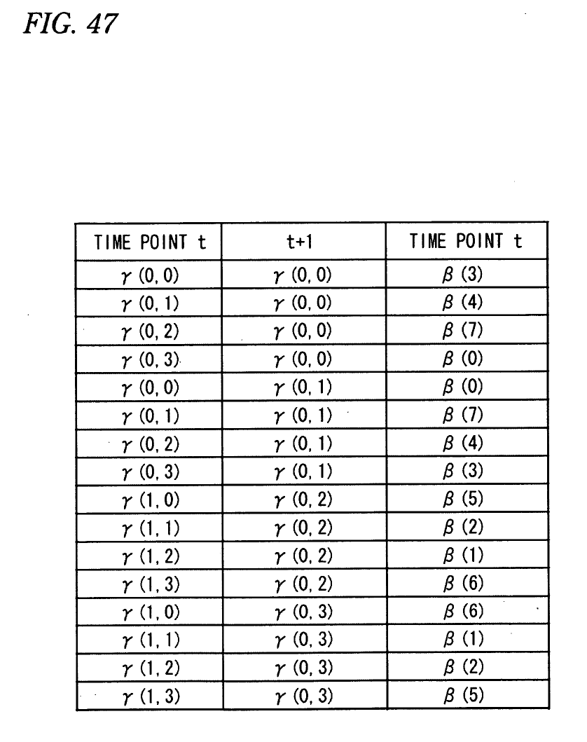

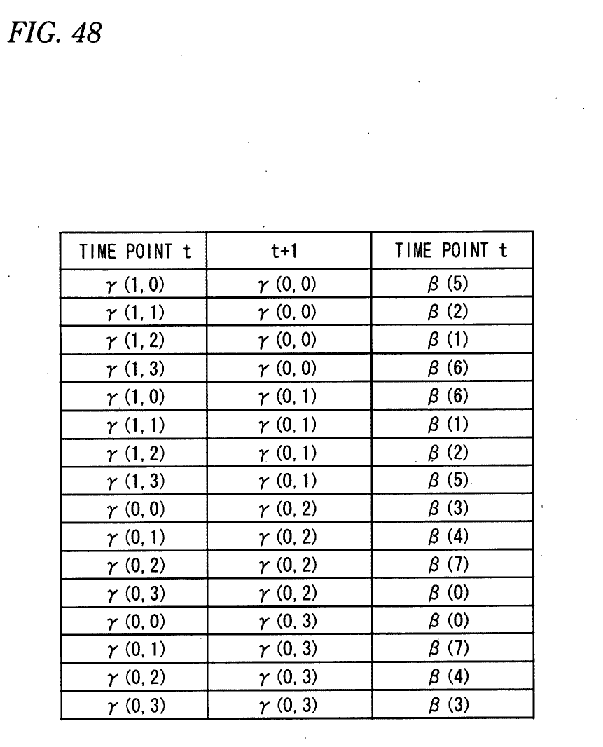

As two β metric processes, the process of adding all input elements in the tables in FIGS. 41 to 48 is performed and then maximum values of the sums are selected.

Referring back to FIG. 33, a cumulative addition unit 2407 is a circuit which cumulatively adds a γ maximum value obtained by the γ maximum value acquiring unit 2405 at appropriate times along the time axis. A subtraction β compression unit 2408 is a circuit which is enabled only at the time of β computation and subtracts a β value from a cumulatively added value from the cumulative addition unit 2407. A β memory 2409 is a memory for storing a result obtained by the subtraction β compression unit 2408, and the size of the result has been reduced to 12 bits.

A cumulative subtraction unit 2410 is a circuit which subtracts values from a final value from the cumulative addition unit 2407 in order to compute a cumulatively added value used at the time of restoration in an addition β restoration unit 2411. The addition β restoration unit 2411 restores an original β value by adding a value from the cumulative subtraction unit 2410 and a value from the β memory 2409. A λ computing unit 2412 corresponds to a λ computing unit of a conventional turbo decoder.

A deinterleaving unit 2413 is a circuit for deinterleaving and rearranging data obtained from the λ computing unit 2412 which has been interleaved. As a result of repetitive operation, a value of a priori probability Le is stored in an Le memory 2414 and is supplied to the γ computing unit 2404.

### SECOND EXAMPLE

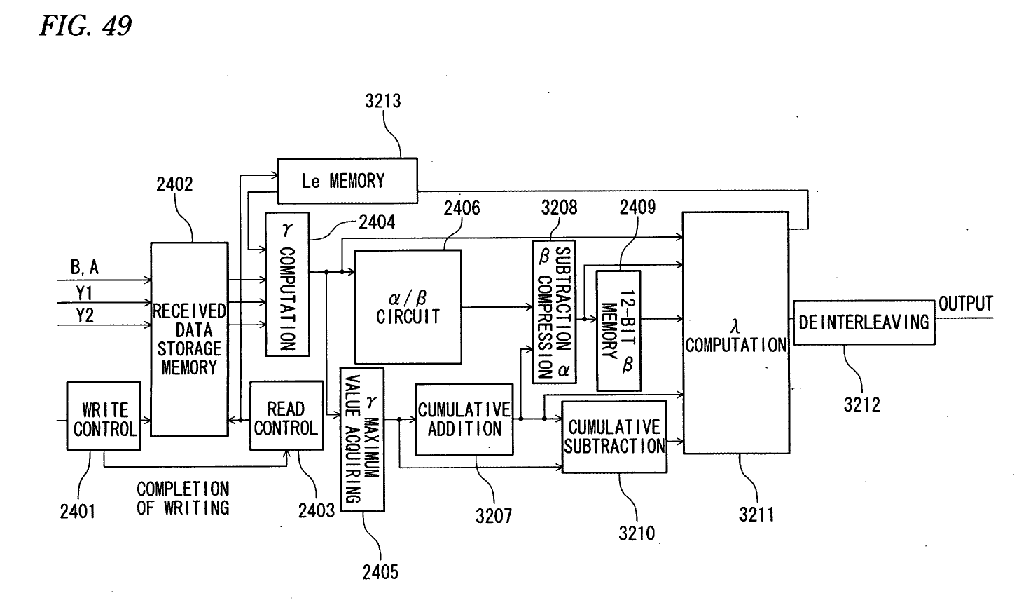

A second example is a turbo decoder which, like the first example, is designed for use in IEEE 802.16 (WiMAX), receives a β compression result and an α compression result as γ inputs to a λ computing unit, and uses a cumulatively added value for Le computation. FIG. 49 is a block diagram illustrating a turbo decoder according to the second example. Components denoted by reference numerals 2401 to 2406 are basically the same as those of the turbo decoder according to the first example illustrated in FIG. 33 and described above. Only differences from the first example will be described below.

In contrast to the cumulative addition unit 2407 in FIG. 33, which performs cumulative addition only for β, a cumulative addition unit 3207 cumulatively adds a β value during β metric computation. When the cumulative addition unit 3207 is switched to α metric computation, the cumulative addition unit 3207 performs initialization and cumulatively adds an α value. A subtraction αβ compression unit 3208 is a circuit common to α computation and β computation, performs subtraction processing for β during β computation, and performs subtraction processing for α during α computation. Although a λ computing unit 3211 is not different from the conventional turbo decoder described with reference to FIG. 9 in λ computation method itself, a cumulative value has been subtracted from data to be inputted to the λ computing unit 3211. Accordingly, as has been described above with reference to FIG. 32, an α cumulatively added value and a β cumulatively subtracted value may need to be taken into consideration at the time of Le computation.

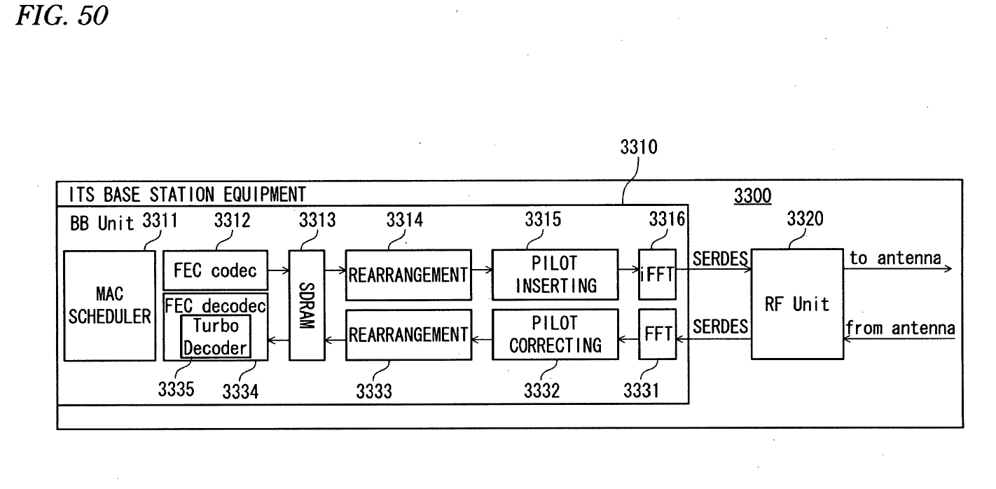

FIG. 50 is a block diagram illustrating a base station using a turbo decoder according to one embodiment. An ITS base station equipment 3300 illustrated in FIG. 50 has a base band unit 3310 and an RF unit 3320. The base band (BB) unit 3310 has a MAC scheduler 3311 which performs scheduling of the base station equipment 3300.

Data to be transmitted is subjected to FEC (Forward Error Correction) coding using turbo codes in an FEC codec 3312. The coded data is stored in an SDRAM 3313 for MAP generation and is subjected to rearrangement from a logical channel format into a physical channel format in a rearrangement unit 3314. In a pilot inserting unit 3315, a pilot signal is inserted into the data. The data, into which the pilot signal has been inserted, is subjected to an inverse Fourier transform in an inverse Fast Fourier transform unit (iFFT) 3316 and is then serially transferred to an RF unit 3320 at high speed. The transferred data is converted into an RF signal by the RF unit 3320 and is transmitted to an antenna (not illustrated).

An RF signal received by the antenna is inputted to the RF unit 3320. After the RF signal is converted into digital data, the RF signal is serially transferred to the base band unit 3310 at high speed. The transferred data is inputted to a Fast Fourier transform unit 3331 and is Fast Fourier transformed into a frequency domain. A pilot signal is received from the data obtained after the transform in a pilot correcting unit 3332, and signal correction is performed based on the pilot signal. The data obtained after the correction is rearranged from the physical channel format into the logical channel format in a rearrangement unit 3333. The rearranged data is stored in the SDRAM 3313 and is decoded by an FEC decodec 3334. The FEC decodec 3334 includes a turbo decoder 3335 according to an embodiment. The turbo decoder may be, for example, the turbo decoder according to the first example illustrated in FIG. 27 or the turbo decoder according to the second example illustrated in FIG. 33.

According to the embodiment, a disclosed alpha and beta metric computing unit concurrently computes a plurality of processes in a time sequence. Therefore, the computation time for α metrics or β metrics may be reduced. The presence of a compression unit which compresses the α metrics or β metrics using a cumulatively added value of a maximum value of a state transition probability and a storage unit which stores the α metrics or β metrics compressed by the compression unit allows a reduction in the memory capacity of the storage unit.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment has been described in detail, it should be understood that the various changes, substitutions, and alterations could be made hereto without departing from the spirit and scope of the invention.

1. A turbo decoder comprising:
a state transition probability computing unit which obtains a state transition probability from data, a flag, and a priori probability from a previous stage;
an alpha and beta metric computing unit which obtains an alpha metric and a beta metric from the state transition probability by computing a plurality of processes concurrently in a time sequence; and
a normalization unit which obtains decoded data and a priori probability for a next stage based on the state transition probability obtained by the state transition probability computing unit and on the alpha metric and the beta metric obtained by the alpha and beta metric computing unit.

2. The turbo decoder according to claim 1, wherein
the alpha and beta metric computing unit comprises:
a holding circuit which holds a state transition probability at time point t; and
an adding circuit which adds the state transition probability at time point t held by the holding circuit and a state transition probability at time point t+1.

3. The turbo decoder according to claim 1, further comprising:
a compression unit which compresses at least one of the alpha metric and the beta metric using a cumulatively added value of a maximum value of the state transition probability; and
a storage unit which stores at least one of the alpha metric and the beta metric compressed by the compression unit.

4. A turbo decoder comprising:
a state transition probability computing unit which obtains a state transition probability from data, a flag, and a priori probability from a previous stage;
an alpha and beta metric computing unit which obtains an alpha metric and a beta metric from the state transition probability obtained by the state transition probability computing unit;
a normalization unit which obtains decoded data and a priori probability for a next stage based on the state transition probability obtained by the state transition probability computing unit and on the alpha metric and the beta metric obtained by the alpha and beta metric computing unit;
a compression unit which compresses at least one of the alpha metric and the beta metric using an accumulated value of a maximum value of the state transition probability; and
a storage unit which stores at least one of the alpha metric and the beta metric compressed by the compression unit.

5. The turbo decoder according to claim 4, further comprising:
a restoration unit which restores the compressed one of the alpha metric and the beta metric stored in the storage unit to a state before the compression.

6. The turbo decoder according to claim 5, further comprising:
a cumulative addition unit which cumulatively adds a maximum value of the state transition probability.

7. The turbo decoder according to claim 5, further comprising:
a cumulative subtraction unit which cumulatively subtracts a maximum value of the state transition probability.

8. The turbo decoder according to claim 4, wherein the alpha and beta metric computing unit concurrently computes a plurality of processes in a time sequence.

9. The turbo decoder according to claim 4, wherein
the compression unit compresses both the alpha metric and the beta metric,
the storage unit stores at least one of the alpha metric and the beta metric compressed by the compression unit, and
the normalization unit obtains decoded data and a priori probability for a next stage based on the compressed alpha metric and the compressed beta metric.

10. The turbo decoder according to claim 9, further comprising:
a cumulative addition unit which cumulatively adds a maximum value of the state transition probability.

11. The turbo decoder according to claim 9, further comprising:
a cumulative subtraction unit which cumulatively subtracts a maximum value of the state transition probability.

12. The turbo decoder according to claim 9, wherein the alpha and beta metric computing unit concurrently computes a plurality of processes in a time sequence.

13. A Base station comprising:
a base band unit with a decoding unit including the turbo decoder according to claim 1; and
an RF unit which performs one of converting digital data from the base band unit into an RF signal to transmit the RF signal to an antenna and converting an RF signal from the antenna into digital data to transmit the digital data to the base band unit.

14. A Base station comprising:
a base band unit with a decoding unit including the turbo decoder according to claim 4; and
an RF unit which performs one of converting digital data from the base band unit into an RF signal to transmit the RF signal to an antenna and converting an RF signal from the antenna into digital data to transmit the digital data to the base band unit.

15. A decoding method for a turbo code comprising:
obtaining a state transition probability from data, a flag, and a priori probability from a previous stage;
obtaining at least one of an alpha metric and a beta metric from the state transition probability by computing a plurality of processes concurrently in a time sequence; and
obtaining decoded data and a priori probability for a next stage based on the state transition probability and on at least one of the alpha metric and the beta metric.

16. A decoding method for a turbo code comprising:
obtaining a state transition probability from data, a flag, and a priori probability from a previous stage;
obtaining at least one of an alpha metric and a beta metric from the state transition probability;
obtaining decoded data and a priori probability for a next stage based on the state transition probability and at least one of the alpha metric and the beta metric;
compressing at least one of the alpha metric and the beta metric obtained using a cumulatively added value of a maximum value of the state transition probability; and
storing at least one of the compressed alpha metric and the compressed beta metric.
